(19) United States
(12) Patent Application Publication
(10) Pub. No.: US 2026/0182365 A1
(43) Pub. Date: Jun. 25, 2026

(54) SPIRAL AND SNAIL WOUND HIGH VOLTAGE RESISTOR OVER SILICON SUBSTRATE

(71) Applicant: Texas Instruments Incorporated, Dallas, TX (US)

(72) Inventors: Byron Lovell Williams, Plano, TX (US); Jeffrey A. West, Dallas, TX (US); Elizabeth Stewart, Dallas, TX (US)

(21) Appl. No.: 19/001,221

(22) Filed: Dec. 24, 2024

(51) Int. Cl. H01L 23/522; H01L 23/528; H10D 80/20

(52) U.S. Cl. CPC H10W 20/498; H10D 80/213; H10W 20/42; H10W 20/43

(57) ABSTRACT

An integrated circuit includes a multilevel metallization structure having a dielectric layer over a semiconductor layer, a pad metal layer on the dielectric layer, and a thin-film resistor layer located over the pad metal layer, as well as a thin-film resistor having a spiral winding of the thin-film resistor layer with multiple turns in the thin-film resistor layer, the spiral winding connected between first and second resistor terminals of the pad metal layer. A second thin-film resistor with a second spiral winding can include multiple turns interleaved with the turns of the first spiral winding.

### BACKGROUND

Electronic devices such as integrated circuits (ICs) may have circuits and/or components in multiple voltage domains, such as low voltage logic circuitry in a low voltage domain, and communications driver, amplifier, or sensing circuits in a second, high voltage domain. Resistor divider networks can be used for low voltage circuits to sense high voltages in a single device and to prevent damaging current flow between a high voltage node and low voltage sensing circuits. Discrete resistor networks can be soldered onto a host printed circuit board (PCB) outside the IC with large spacings between the two ends of each resistor to prevent air breakdown across the resistor body. However, this is expensive and takes up significant space in the system to meet the safety requirements that prevent air breakdown.

### SUMMARY

In one aspect, an integrated circuit includes a multilevel metallization structure having a dielectric layer over a semiconductor layer, a pad metal layer on the dielectric layer, and a thin-film resistor layer located over the pad metal layer, and a thin-film resistor having a spiral winding of the thin-film resistor layer with multiple turns in the thin-film resistor layer, the spiral winding connected between first and second resistor terminals of the pad metal layer.

In another aspect, an integrated circuit includes a multilevel metallization structure and first and second thin-film resistors. The multilevel metallization structure has a dielectric layer over a semiconductor layer, a pad metal layer on the dielectric layer, and a thin-film resistor layer located over the pad metal layer. The first thin-film resistor has a first spiral winding with multiple turns in the thin-film resistor layer, the first spiral winding connected between first and second resistor terminals of the pad metal layer. The second thin-film resistor is spaced apart from the first thin-film resistor and has a second spiral winding with multiple turns in the thin-film resistor layer, the second spiral winding connected between the second resistor terminal and a third resistor terminal of the pad metal layer.

### BRIEF DESCRIPTION OF THE DRAWINGS

FIG. 1 is a partial sectional side elevation view of a portion of an electronic device with an integrated voltage divider in a multilevel metallization structure over a semiconductor layer.

FIG. 1A is a partial sectional top view of the electronic device of FIG. 1.

FIGS. 1B-1G are partial top views of a pair of spiral co-wound thin-film resistors.

FIGS. 1H-1N are partial top views of a snail shaped spiral thin-film resistor circuit with spiral co-wound wound thin-film resistors.

FIG. 2 is a flow diagram of a method of fabricating an electronic device.

FIGS. 3-36 are partial sectional side elevation views of the device of FIG. 1 undergoing metallization structure fabrication processing according to the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. The example structures include layers or materials described as over or on another layer or material, which can be a layer or material directly on and contacting the other layer or material where other materials, such as impurities or artifacts or remnant materials from fabrication processing may be present between the layer or material and the other layer or material. Unless otherwise stated, “about,” “approximately,” or “substantially” preceding a value means +/−10 percent of the stated value. One or more structures, features, aspects, components, etc., may be referred to herein as first, second, third, etc., for ease of description in connection with a particular drawing, where such are not to be construed as limiting with respect to the claims. Various disclosed structures and methods of the present disclosure may be beneficially applied to an electronic device, manufacturing, testing, and/or operating an electronic device such as an integrated circuit. While such examples may be expected to provide various improvements, no particular result is a requirement of the present disclosure unless explicitly recited in a particular claim.

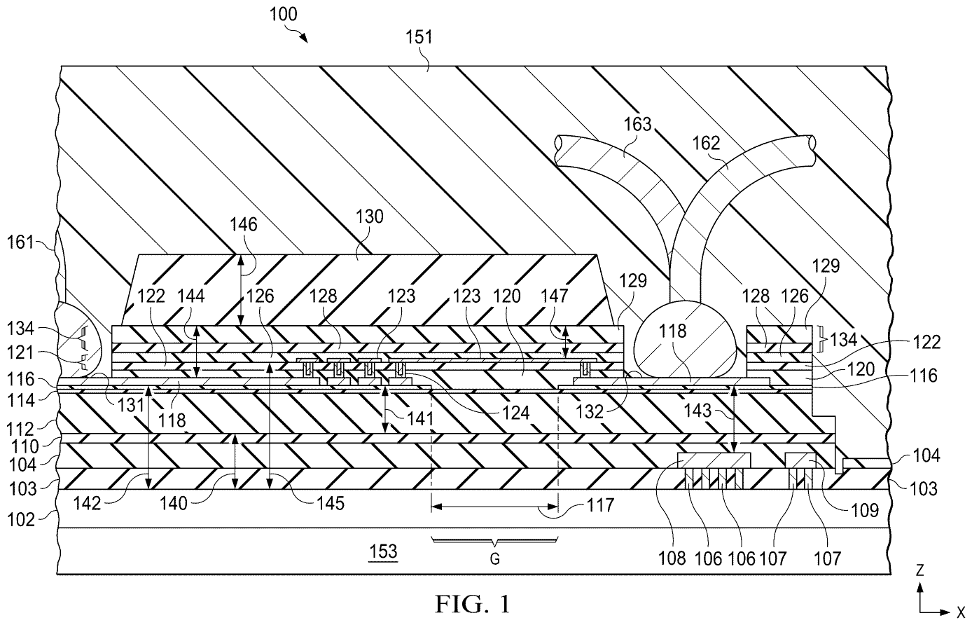

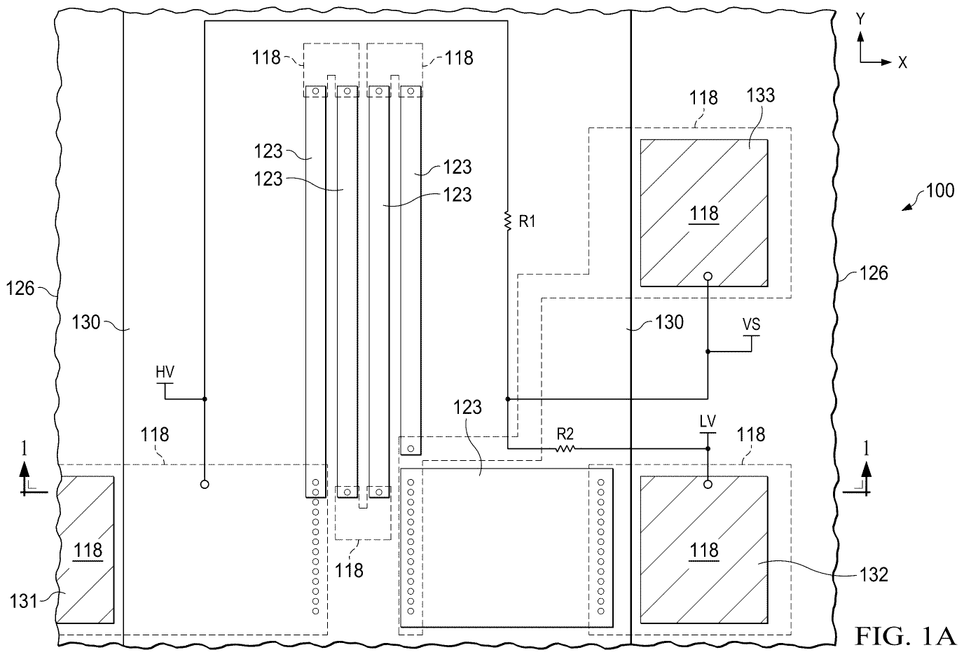

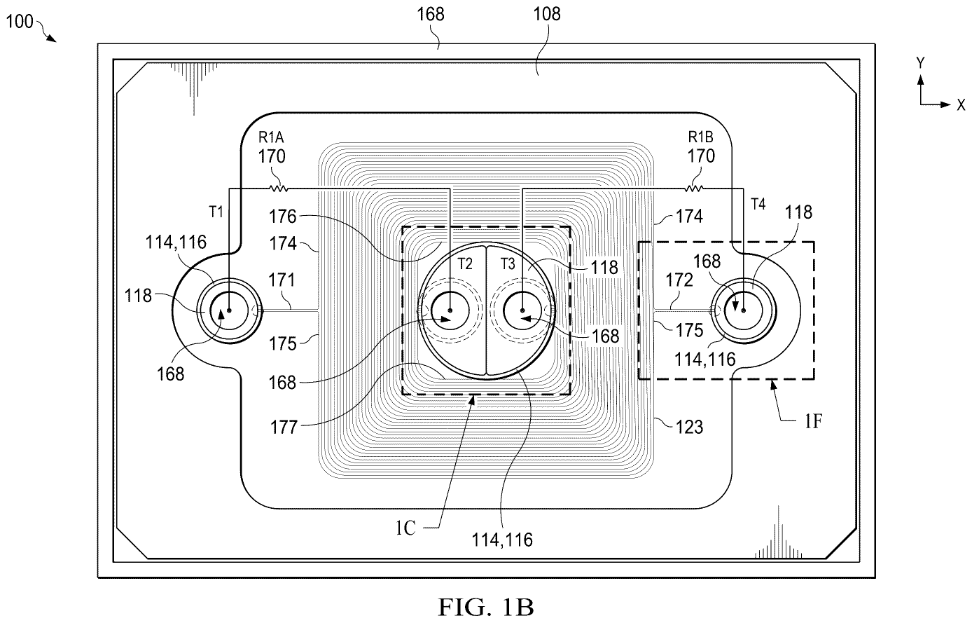

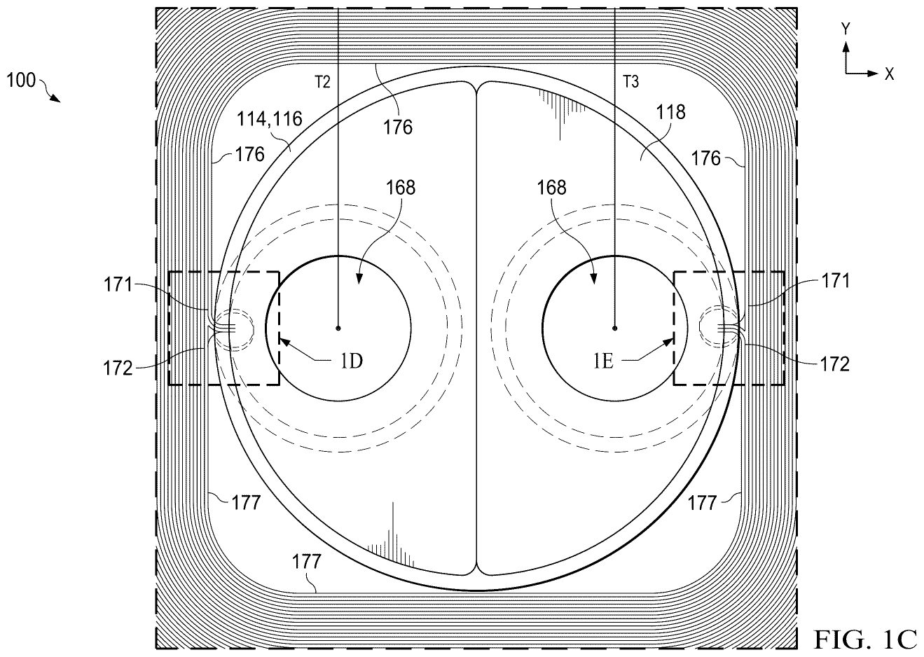

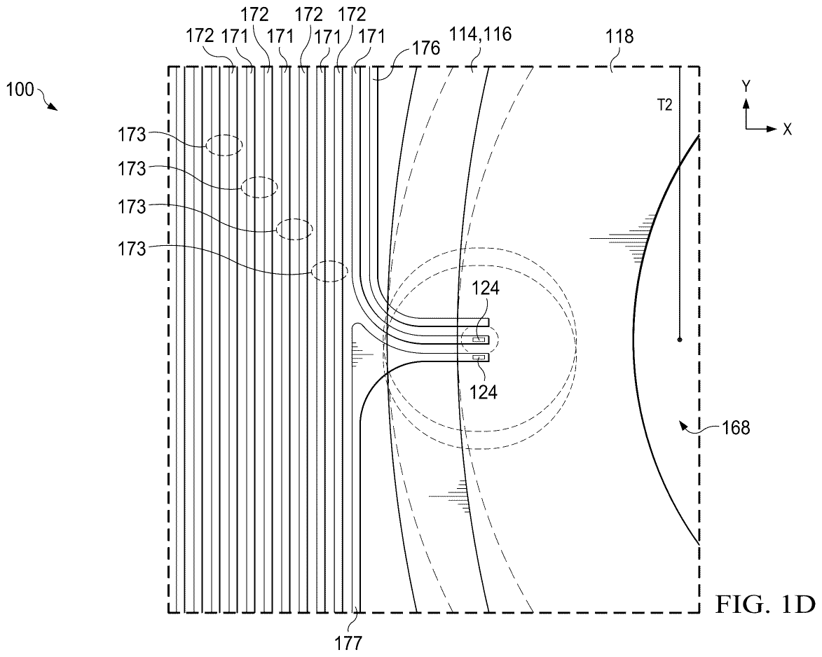

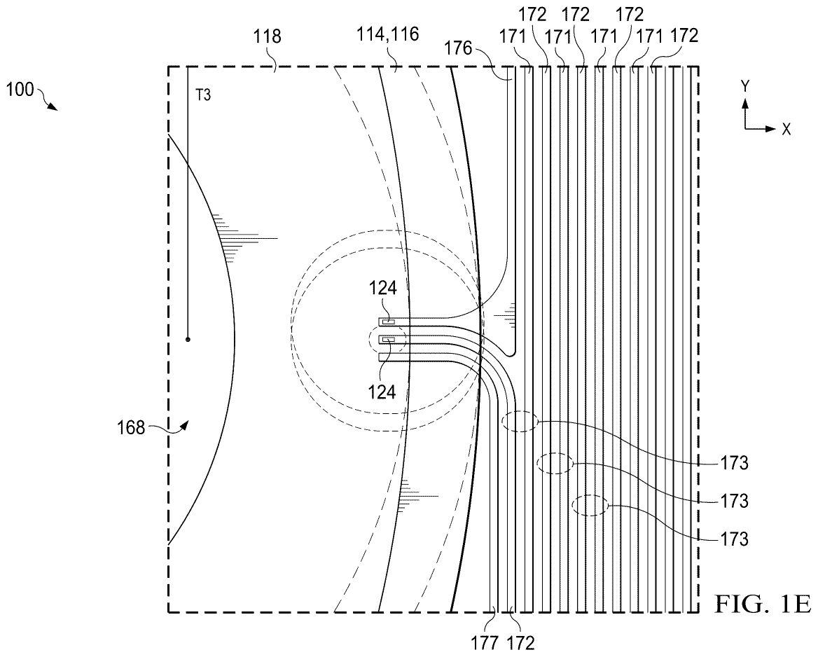

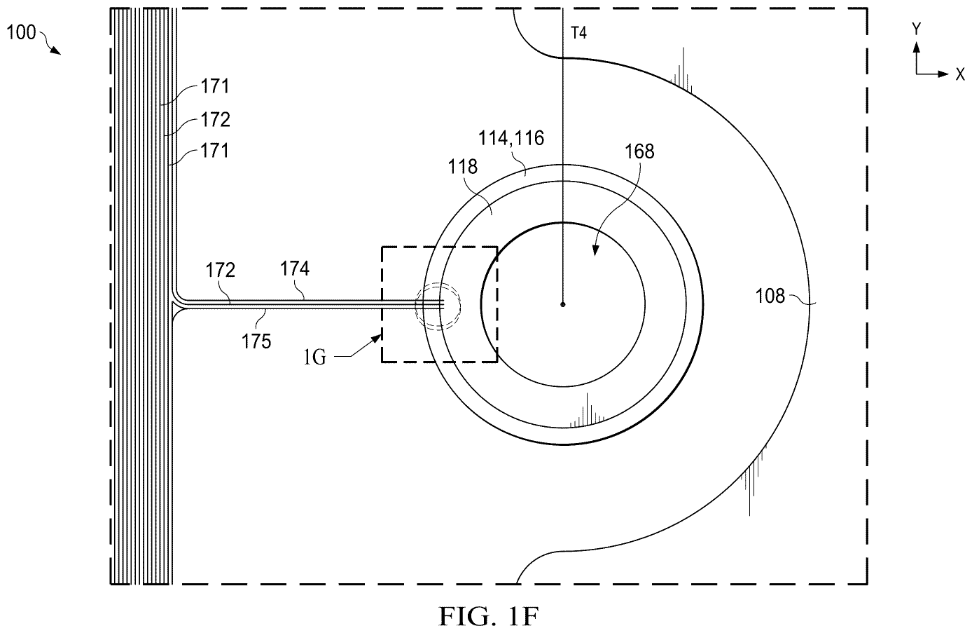

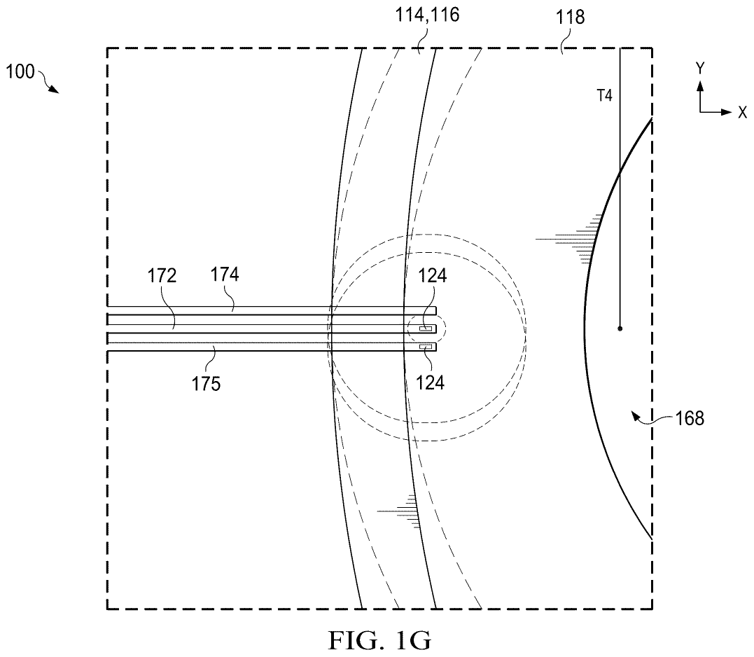

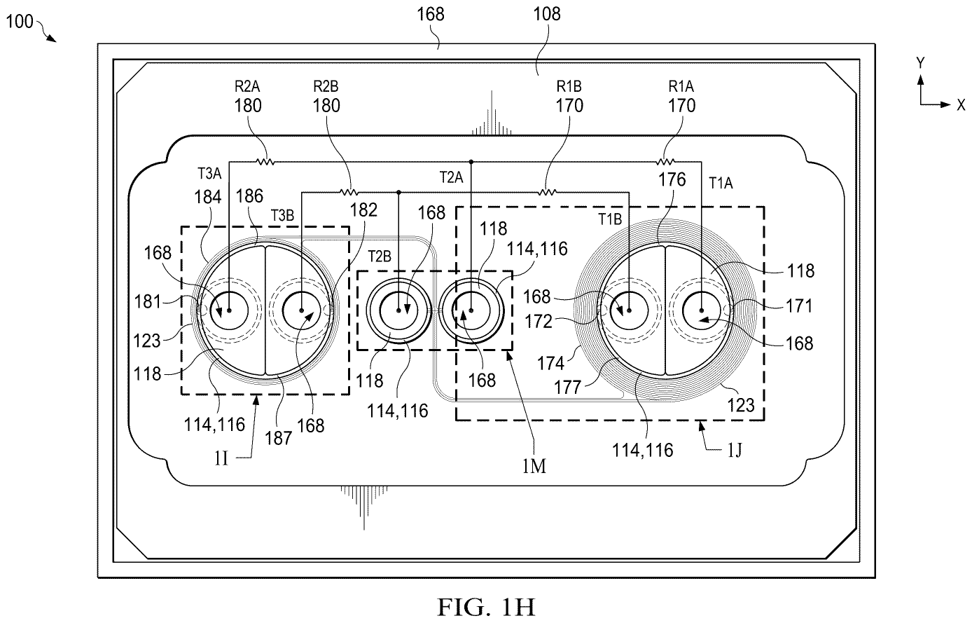

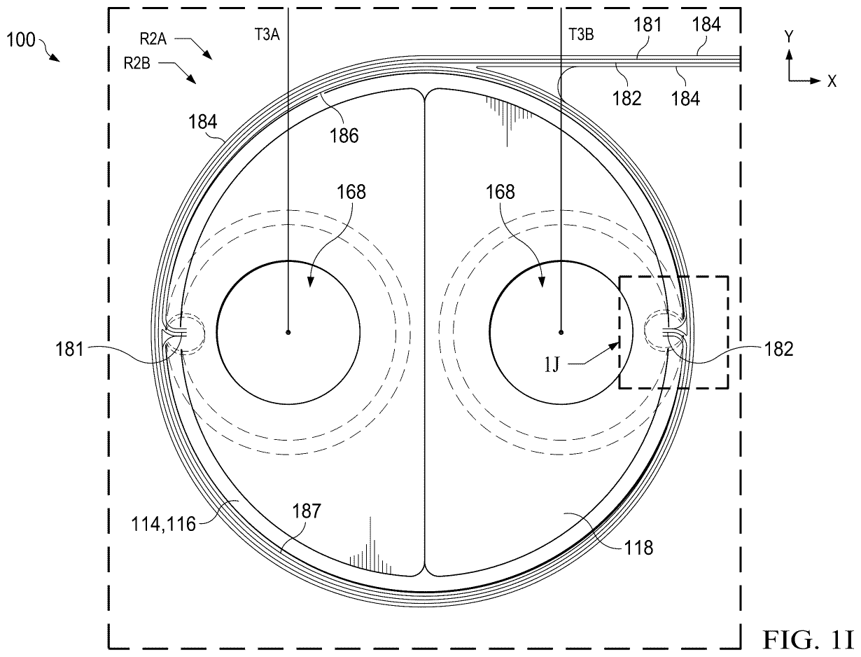

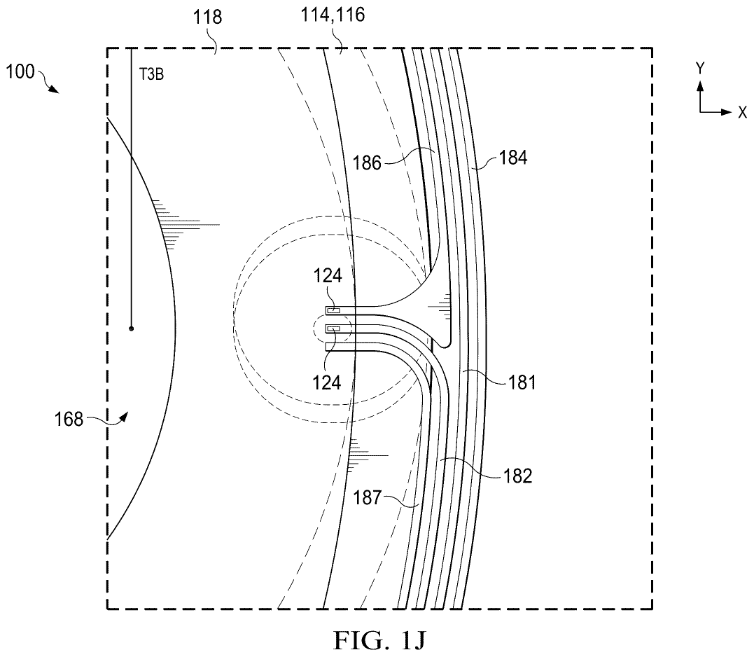

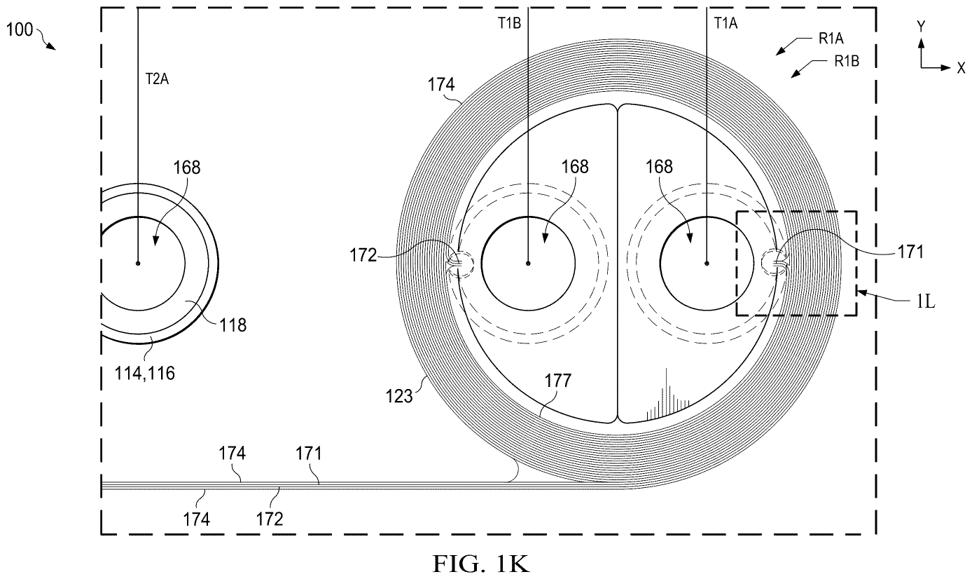

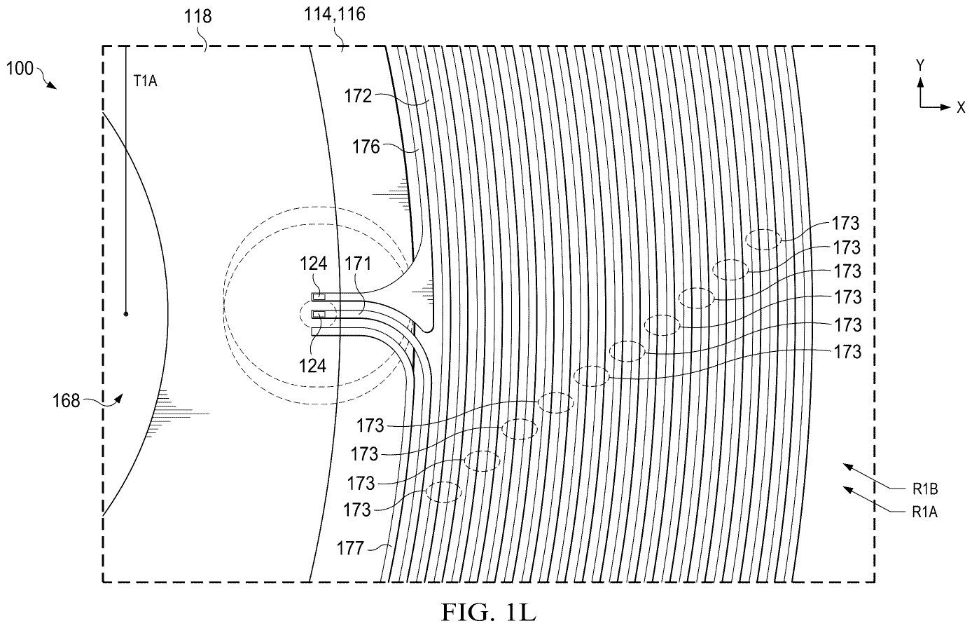

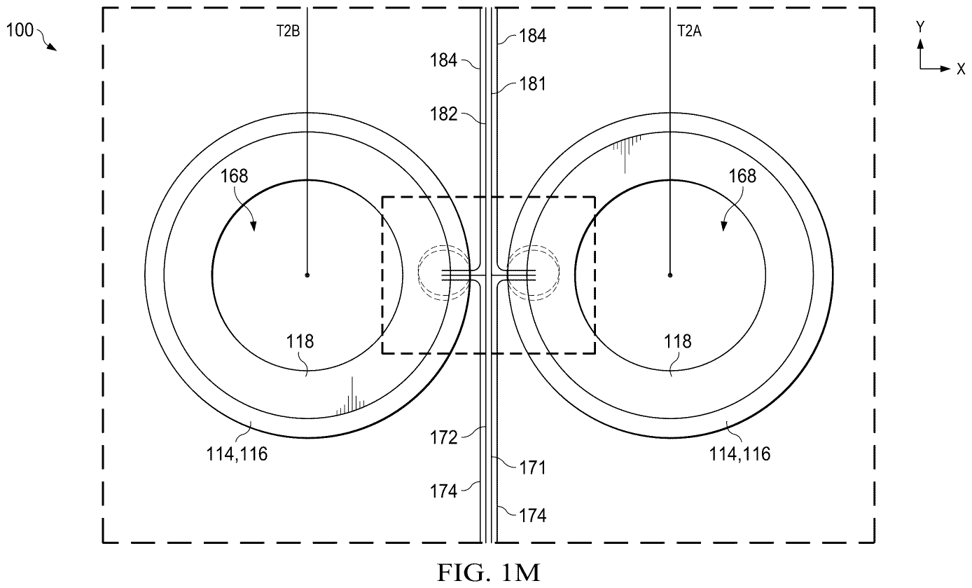

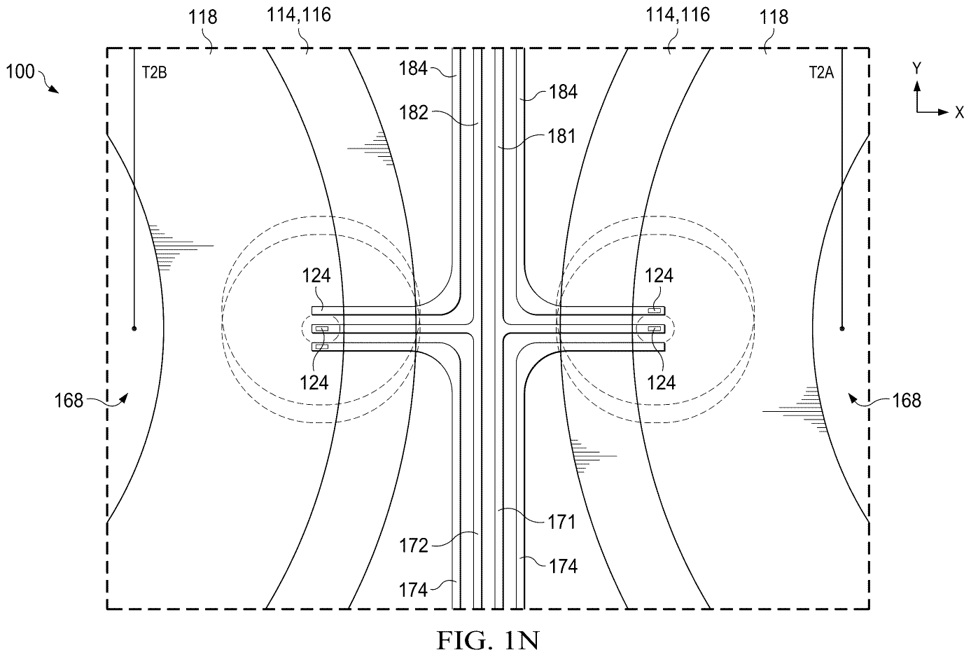

FIGS. 1-1N show an integrated circuit 100 (also sometimes referred to herein as an electronic device) with one or more integrated resistive voltage dividers in a multilevel metallization structure over a semiconductor layer 102, sometimes referred to as a substrate 102. Described example implementations of the electronic device 100, such as integrated circuits provide a resistor or resistor network on a die fabricated in a metallization structure located over the silicon substrate semiconductor layer 102. The metallization structure includes silicon dioxide that provide high voltage insulation between the resistors and the underlying semiconductor layer 102. Certain examples enclose or cover the resistors with high electrical breakdown strength dielectric materials and the die is encapsulated within a multichip module (MCM) with mold compound or other package structure 151 that can mitigate or avoid air breakdown over the resistor or resistors to create high voltage operating capability with high precision thin-film resistors for sensing or other applications. The die in one example is a resistor divider die in a multichip module that is mounted on a lead frame or die attach pad 153 using a die attach film (DAF) or other suitable adhesive (not shown), for example, having a conductive adhesive with a thickness of approximately 10-20 μm, that bonds the bottom side of the semiconductor layer 102 to the die attach pad 153. The die can be packaged along with one or more additional dies (not shown), such as a sensor circuit die with transistors forming a sensing amplifier. In another example, the resistor or resistor network is included in a die with other circuit components (e.g., one or more transistors, diodes, capacitors, inductors, transformers, etc.) of an integrated circuit, or electronic device, 100.

In one example, the semiconductor layer 102 is or includes a p-type silicon layer, a silicon-germanium layer, a silicon-on-insulator (SOI) structure, or another layer or layers having semiconductor material. The semiconductor layer 102 in some examples may be separated from a starting semiconductor wafer or a semiconductor layer over a wafer, such as an epitaxial layer over a wafer. In various examples the semiconductor layer 102 may be referred to as a semiconductor substrate. In one implementation, the electronic device 100 also includes further circuitry (e.g., low voltage logic circuits, not shown) such as transistors formed on and/or in the semiconductor layer 102, although not a requirement of all possible implementations.

As shown in FIG. 1, the integrated circuit 100 includes a multilevel metallization structure with a pre-metal dielectric (PMD) layer 103 disposed over (e.g., on and directly contacting) a top side of the semiconductor layer 102, and first and second metallization levels above the PMD layer 103. Other examples can include a different number of metallization levels. In one example, the PMD layer 103 is or includes silicon dioxide (e.g., SiO₂) with a thickness of approximately 3.0 μm. The pre-metal level and the metallization structure levels extend in respective planes of respective orthogonal first and second directions X and Y and are arranged in a stack along a third direction Z that is orthogonal to the first and second directions X and Y. In the illustrated example, the second (e.g., top) level includes resistor terminals having an exposed top side that allows bond wire or other connection to the resistor terminals for electrical coupling to a second die or to device leads or other terminals of the integrated circuit 100.

The first level of the metallization structure has a first interlevel dielectric (ILD) layer 104 above (e.g., on and directly contacting) the PMD layer 103 of approximately 3.0 to 5.0 μm in one example. In one example, the first ILD layer 104 is or includes silicon dioxide with a thickness of approximately 4.4 μm. The PMD level includes conductive contacts 106 and conductive cylindrical peripheral contacts 107 on the semiconductor layer 101, for example, circles having diameters of approximately 0.9 μm or can be a trench that fully surrounds the die as part of a scribe seal. The contacts 106 and 107 in one example are or include tungsten but can be or include one or more other conductive metals and can include low contact resistance metal such as titanium and/or titanium nitride (not shown) in a single or a bilayer structure to contact and provide an interface to the top surface of the semiconductor layer 102. The contacts 106 and 107 extend through the PMD layer 103 along the third direction Z in FIG. 1.

The first metallization level in one example has aluminum conductive routing features or traces patterned according to a device design, including a conductive metal grounded fill feature 108 and a peripheral conductive metal seal structure 109 as shown in FIG. 1. The peripheral contacts 107 and the peripheral metal structure 109 near the outer periphery of the illustrated portion of the integrated circuit 100 can help protect against cracks and mechanical stress on the integrated circuit 100 and/or provide a barrier against ingress from external ionic contamination at the die edge, although not a strict requirement of all possible implementations.

In other implementations, different dielectric and/or conductive metal materials can be used (e.g., copper metal features, silicon oxynitride dielectric layers, etc.). The first level also includes a dielectric layer 110 above (e.g., on and directly contacting) the first ILD layer 104. In one example, the dielectric layer 110 is or includes silicon oxynitride of any suitable stoichiometry (e.g., SiOₓN_{y}), and can be referred to as a first silicon oxynitride layer. In one example, the first ILD layer 104 has a planarized top surface that extends above the top surface of the first metal layer conductive features 108 and 109 by approximately 1.4 μm. In one example, the top surface of the dielectric layer 110 is spaced apart from the top side of the semiconductor layer 102 by a distance 140 of approximately 8.3 μm along the third direction Z.

The metallization structure includes a second level with a second ILD layer 112 over (e.g., on and contacting) the dielectric layer 110. In one example, the second ILD layer 112 is or includes silicon dioxide of any suitable stoichiometry and thickness, for example, approximately 6.6 μm. The second level also includes a dielectric layer 114, e.g., silicon oxynitride, over (e.g., on and contacting) the top surface of the second ILD layer 112, for example, approximately 0.3 to 0.8 μm thick, and a dielectric layer 116 over (e.g., on and contacting) a first portion of the dielectric layer 114. In one example, the dielectric layer 116 is or includes an inorganic dielectric material such as silicon nitride (e.g., SiN of any suitable stoichiometry) and can be of any suitable thickness, for example, approximately 0.55 μm as deposited. In one example, the top surface of the dielectric layer 116 is spaced apart from the top surface of the dielectric layer 110 by a spacing distance 141 of approximately 7.4 to 7.9 μm along the third direction Z. In some examples, the high voltage operation capabilities can be enhanced by use of the silicon oxynitride/silicon nitride or other suitable dielectric bilayer of the dielectric layers 114, 116 under a pad metal layer 118. The bilayer in one example includes silicon nitride for the dielectric layer 116 with the gap G and the silicon oxynitride for the dielectric layer 114. Such a bilayer is sometimes referred to as a silicon nitride/oxynitride (SO) bilayer 114, 116, or simply as “SO bilayer”. A trench in the SO bilayer 114, 116 extends through the silicon nitride layer 116 and partially into the oxynitride layer.

The second metallization level in one example has aluminum conductive routing features or traces such as the pad metal layer 118, referred to herein as a pad metal layer, on the dielectric layer 116 and patterned according to a device design. In other examples, a different metal material can be used. Portions of the pad metal layer 118 are exposed outside a dielectric seal structure 121 including dielectric sublayers 122, 126 to allow electrical connection by bond wires or other suitable conductive connection structures. The features of the pad metal layer 118 of the second level include a first resistor terminal 131 (FIGS. 1 and 1A), a second resistor terminal 132 (FIGS. 1 and 1A, and a third resistor terminal 133 (FIG. 1A)). The illustrated example has a lateral gap G in the dielectric layer 116 between the first and second resistor terminals 131 and 132 with a gap distance 117. In one example, the gap distance 117 is designed based on a voltage rating of the integrated circuit 100 to mitigate or avoid lateral voltage breakdown between high and low voltage domain levels along an interface between the respective dielectric layers 114 and 116 based on an operating voltage between the first and second resistor terminals 131 and 132.

The pad metal layer 118 is covered by a third ILD layer 120 that extends over (e.g., on and directly contacting) the patterned features of the pad metal layer 118 and the top surfaces of the dielectric layer 116 and the dielectric layer 114 in the gap G of the dielectric layer 116. In one example, the third ILD layer 120 is or includes silicon dioxide of any suitable stoichiometry and thickness, for example, approximately 1.5 to 2.5 μm over the pad metal layer 118. The integrated circuit 100 also includes a resistor, also referred to as a film resistor, including portions of a thin-film resistor (TFR) layer 123 enclosed by first and second sublayers 122 and 126 of the dielectric seal structure 121. The TFR layer 123 is located on the first sublayer 122 of the dielectric seal structure 121, and the second sublayer 126 of the dielectric seal structure is on the TFR layer 123 such that the seal structure 121 encapsulates the TFR layer 123. In one example, the first and second sublayers 122 and 126 are or include silicon oxynitride of any suitable stoichiometry and thicknesses, such as approximately 0.2 μm and 0.1 μm, respectively).

As further shown in FIG. 1, the integrated circuit 100 in one example has a further dielectric layer 128 over (e.g., on and directly contacting) a top surface of the second sublayer 126 of the dielectric seal structure 121. In one example, the dielectric layer 128 is or includes silicon dioxide of any suitable stoichiometry and thickness, for example, approximately 1.0 μm. Another dielectric layer 129 is located over (e.g., on and directly contacting) a top surface of the dielectric layer 128. In one example, the dielectric layer 129 is or includes silicon oxynitride of any suitable stoichiometry and thickness, for example, approximately 2.8 μm. The dielectric layers 128 and 129 in one example form a bilayer protective overcoat (PO) 134 as shown in FIG. 1, which is located over the TFR layer 123 (e.g., spaced apart from an X-Y plane of the TFR layer 123 along the third direction Z). The protective overcoat 134 in one example has a thickness of at least 3.5 μm along the third direction Z, such as approximately 3.8 μm or more. The protective overcoat 134 in one example includes an inorganic dielectric layer 129 (e.g., SiON) and an inorganic dielectric layer 128 (e.g., SiO₂). In the illustrated example, openings in the dielectric layer 129 and the underlying layers 128, 126, 122, and 120 expose the first, second, and third resistor terminals 131, 132, and 133. The integrated circuit 100 in one example also includes a polyimide (PI) layer 130 over (e.g., on and directly contacting) the dielectric layer 129. In one example, the protective overcoat 134 is located over the TFR layer 123 and includes a dielectric layer (e.g., SiON layer 129), and the polyimide layer (130) is located over the protective overcoat 134. Openings in the dielectric layer (129) and the protective overcoat 134 expose the first, second and third resistor terminals 131, 132 and 133.

The electronic device 100 can include one or more thin-film resistors formed by corresponding structures in the TFR layer 123. FIG. 1A shows a serpentine resistor structure forming a voltage divider. FIGS. 1B-1N show spiral wound thin-film resistor structures forming one or more voltage dividers with individual thin-film resistor structures formed in the TFR layer 123 that can be referred to as spiral resistors. FIGS. 1B-1G show one example with a pair of spiral co-wound thin-film resistors, and FIGS. 1H-1N show a snail shaped spiral thin-film resistor circuit with individual divider circuits that include a pair of spiral co-wound thin-film resistors.

FIG. 1A shows a top view of the integrated circuit 100 including a schematic circuit drawing. The TFR layer 123 is located over portions of the pad metal layer 118 and are connected to the pad metal layer 118 by vertical metal interconnects or vias 124 as shown in FIG. 1. In one example patterned features of the TFR layer 123, which may include silicon and chromium (e.g., SiCr) of any suitable thickness and stoichiometry, forms a first resistor R1 and a second resistor R2 as shown in FIG. 1A. In one example, the TFR layer 123 comprises silicon (Si), chromium (Cr) and carbon (C) (e.g., SiCCr) of any suitable thickness and stoichiometry. As shown in FIG. 1, a first location of the TFR layer 123 is connected to the first resistor terminal 131 by a first vertical interconnect 124, and a second location of the TFR layer 123 is connected to the second resistor terminal 132 by a second vertical interconnect 124. In one example, the vertical interconnects 124 include a low contact resistance metal layer (single or bilayer, such as titanium and titanium nitride of any suitable thickness and stoichiometry) along bottoms and sidewalls of corresponding cylindrical via holes or openings through the first sublayer 122 of the dielectric seal structure 121 and the third ILD layer 120. The vertical interconnects 124 are filled with conductive metal, such as tungsten in one example, to provide a low impedance electrical connection of the first location of the TFR layer 123 to the first resistor terminal 131 and of the second location of the TFR layer 123 to the second resistor terminal 132.

As shown in FIG. 1A, moreover, the first resistor R1 has a serpentine shape extending in the TFR layer 123 along the second direction Y and turnaround end portions in the pad metal layer 118. As further shown in FIG. 1A, moreover, the third resistor terminal 133 is connected to a node that joins the first and second resistors R1 and R2 to form a resistive divider sensing node labeled “VS” in FIG. 1A. The first resistor R1 is connected between the first terminal (e.g., which can be connected to a high voltage node of the integrated circuit 100, labeled “HV” in FIG. 1A) and the third resistor terminal 133 at the sensing node VS. The example second resistor R2 of the resistive divider arrangement is connected between the second resistor terminal 132 at a low voltage node (e.g., labeled “LV” in FIG. 1A) of the integrated circuit 100 and the third resistor terminal 133.

In one implementation, the linear segments of the TFR layer 123 have lateral widths of approximately 0.8 μm and the segments of the TFR layer 123 are spaced apart from one another by a distance of approximately 1.2 μm. As further shown in FIG. 1, the TFR layer 123 is spaced apart from the semiconductor layer 102 by a spacing distance 145 of approximately 9 to 28 μm or approximately 2 to 3 μm more than the spacing distance 142 of the pad metal layer 118 from the top surface of the semiconductor layer 102, where the spacing distance 145 in one example is approximately 12.0 or more and approximately 21 μm or less, such as approximately 19 μm along the third direction Z. In the illustrated example, the high voltage node (HV) at the first resistor terminal 131 is spaced apart from the semiconductor layer 102 along the third direction Z by a spacing distance 142 determined according to a rated operating voltage of the integrated circuit 100 (e.g., greater than approximately 10 μm). In one implementation, the spacing distance 142 is approximately 6 μm or more and approximately 25 μm or less (e.g., approximately 16 μm) and the pad metal layer is above and spaced apart from the top surface of the semiconductor layer 102 by the spacing distance 142.

The top surfaces of the conductive metal grounded fill feature 108 and the peripheral conductive metal seal structure 109 of the first metallization level (connected to the substrate 102) are below and spaced apart from the second resistor terminal 132 along the third direction Z by a spacing distance 143 (FIG. 1, e.g., approximately 10 μm) to accommodate a rated operating voltage of the low voltage node (LV) at the second resistor terminal 132 without voltage breakdown. The first resistor R1 in this example has a high voltage and the spacing distance 145 between the resistor R1 and the semiconductor layer (substrate) 102. In one example, the bottom surface of the polyimide layer 130 is spaced apart from the top surface of the pad metal layer 118 along the third direction Z by a spacing distance 144 of approximately 5.6 μm. In one example, the polyimide layer 130 has a thickness 146 along the third direction Z of approximately 8-10 μm. In one example, the bottom surface of the polyimide layer 130 is spaced apart from the top surface of the TFR layer 123 along the third direction Z by a spacing distance 147 of approximately 3.9 μm.

As further shown in FIG. 1, the gap G in the dielectric layer 116 extends between the first and second resistor terminals 131 and 132. In this example, moreover, the resistor R1 having the high voltage drop is positioned at least partially over (e.g., above) the gap G in the dielectric layer 116. The integrated circuit 100 in the illustrated example includes a first bond wire 161 connected to the first resistor terminal 131, a second bond wire 162 connected to the second resistor terminal 132, and a third bond wire 163 connected to the third resistor terminal 133. The integrated circuit 100 in one example includes a molded package structure 151, such as a plastic epoxy mold compound (EMC) or ceramic package that encloses the multilevel metallization structure and the bond wires 161-163 and the die is mounted to a support structure such as die attach pad 153, such as a die attach pad of a starting lead frame.

The resistive layer 123 in one example is over (e.g., above) the pad metal layer 118 (e.g., along the third direction Z in FIG. 1 above). In one example, the line structures of the resistive layer 123 of the resistors 170 are or include silicon chromium with a width of approximately 0.8 μm and a sheet resistance of 900 ohms per square or more. The associated features, dimensions and materials of the described multilevel metallization structure in one implementation provide the resistors 170 having a working voltage of 440 Vrms or more and a transient voltage rating of approximately 4250 V DC or more, 3000 Vrms for 60 seconds. In addition, the resistors 170 have good thermal resistance stability with temperature coefficient of resistance (TCR) of less than approximately 5 ppm/C for high resistance values, and resistors less than approximately 50 Mohm may be more sensitive to via resistance.

FIGS. 1B-1G show one example implementation of the electronic device 100 with a pair of co-wound spiral first and second thin-film resistors 170, schematically indicated R1A and R1B in FIG. 1B. In one example, the resistors 170 have a dielectric layer 116 over a semiconductor layer 102, a pad metal layer 118 on the dielectric layer 116, and a thin-film resistor layer 123 located over the pad metal layer 118 as described above (e.g., FIG. 1). The resistors 170 are constructed in the multilevel metallization structure as described above in connection with FIG. 1 with the patterning and sizing of the resistive layer 123, the pad metal layer 118, the SO bilayer 114, 116 corresponding to the top views of FIGS. 1B-1G. In this example, as in the above described structure shown in FIG. 1, the resistive layer 123 is sealed and located on the first sublayer 122 of the dielectric seal structure, with the second sublayer 126 of the dielectric seal structure located on the resistive layer 123. In addition, the resistive layer 123 is spaced apart from the semiconductor layer 102 in one example by the spacing distance 145 (FIG. 1) of approximately 9.0 μm or more and approximately 29 μm or less, such as approximately 19 μm, with the pad metal layer 118 located above the top surface of the semiconductor layer 102. In addition, the gap G (FIG. 1) in the dielectric layer 116 extends between the resistor terminals T1, T2 (resistor R1A) and T3, T4 (resistor R1B) and the same or a similar gap is provided in the dielectric layer 116 between the resistor terminals in one example. The resistor terminals T1-T4 are connected to the resistor features of the TFR layer 123 by vertical interconnects 124 as best shown in FIGS. 1D, 1E and 1G.

In this example, as in the above described structure shown in FIG. 1, the resistive layer 123 is sealed and located on the first sublayer 122 of the dielectric seal structure, with the second sublayer 126 of the dielectric seal structure located on the resistive layer 123. In addition, the resistive layer 123 is spaced apart from the semiconductor layer 102 in one example by the spacing distance 145 (FIG. 1), with the pad metal layer 118 located above the top surface of the semiconductor layer 102. In addition, the gap G (FIG. 1) in the dielectric layer 116 extends between the first and second resistor terminals and the same or a similar gap is provided in the dielectric layer 116 between the resistor terminals in one example.

The thin-film resistors 170 are co-wound in a spiral arrangement with interleaved spiral windings formed in the TFR layer 123. The first thin-film resistor 170 (e.g., R1A in FIG. 1B) has a first spiral winding 171 of the thin-film resistor layer 123 with multiple turns in the thin-film resistor layer 123. The first spiral winding 171 is connected between respective first and second resistor terminals T1 and T2 of the pad metal layer 118. The first spiral winding 171 has an exterior (e.g., outer) end connected to the first resistor terminal T1 in FIG. 1B and an interior end connected to the second resistor terminal T2 (FIGS. 1B-1D).

The second thin-film resistor 170 (e.g., R1B in FIG. 1) has a second spiral winding 172 with multiple turns of the thin-film resistor layer 123. The second spiral winding 172 is connected between the third and fourth resistor terminals T3 and T4 of the pad metal layer 118, with an exterior (e.g., outer) end connected to the fourth resistor terminal T4 in FIGS. 1B and 1F and an interior end connected to the third resistor terminal T3 (FIGS. 1B, 1C and 1E). The turns of the second spiral winding 172 are interleaved with the turns of the first spiral winding 171. The illustrated example includes multiple turns of the spiral windings 171 and 172 formed in adjacent pairs denoted 173 in FIGS. 1D and 1E. The spiral windings 171 and 172 of the thin-film resistor layer 123 overlie a gap in the pad metal layer 118 as shown in FIGS. 1B-1F.

The respective spiral windings 171 and 172 include linear (e.g., straight) portions of the thin-film resistor layer 123 and turn portions of the thin-film resistor layer 123. The illustrated co-wound interleaved example provides a generally rectangular shape as shown in FIG. 1B, although not a requirement of all possible implementations. In this example, the turn portions of the respective spiral windings 171 and 172 are approximately 90 degrees with four turn portions per winding turn. In other implementations, more or fewer turn portions can be used, and the turn portions of the spiral windings are less than 180 degrees, such as greater than 0 degrees and less than or equal to 90 degrees. In other implementations, the spiral windings can include only curved portions of the thin-film resistor layer 123 (e.g., having no straight or linear portions other than the terminal connection feeds as shown in FIGS. 1H-1N below). The spiral windings 171 and 172 of the thin-film resistor layer 123 in FIGS. 1B-1G overlie respective gaps in the pad metal layer 118.

The example of FIGS. 1B-1G also has electrically inactive dummy resistive layer lines 174, 175, 176, and 177 of the thin-film resistor layer 123 that are positioned adjacent to and spaced apart from a first or last turn of the spiral windings 171 and 172. The first resistor terminal T1 and the fourth resistor terminal T4 are outside an outer extent of the spiral windings 171 and 172. The second resistor terminal T2 and the third resistor terminal T3 are inside an inner extent of the spiral windings 171 and 172. In the illustrated example, the spiral windings 171, 172 are surrounded by dummy line structures with dummy resistive layer line gaps at the connections of the spiral windings 171, 172 to the respective terminals T1-T4. The illustrated example includes an upper interior or inner dummy resistive layer line 176 and a lower interior dummy resistive layer line 177 of the thin-film resistor layer 123. The inner dummy resistive layer lines 176 and 177 are at least partially surrounded by an inner extent of the first and second thin-film resistors 170 to accommodate connections to the interior resistor terminals T2 and T3 (e.g., FIGS. 1B-1E) while providing adjacent dummy lines at least partially surrounded by an inner extent of the first and second thin-film resistors 170. The illustrated example also includes an upper exterior or outer dummy resistive layer line 174 of the thin-film resistor layer 123 and a lower outer dummy resistive layer line 175 of the thin-film resistor layer 123 that at least partially surround an outer extent of the first and second thin-film resistors 170 while allowing access for the connections to the exterior resistor terminals T1 and T4.

As shown in FIGS. 1B-1G, the resistor terminals T1-T4 of the pad metal layer 118 can be contacted by bond wires or other suitable connections through openings 168 in the upper metallization layers (e.g., openings in 120, 122, 126, 128, and 129 in FIG. 1 above). A similar gap 168 can extend around the lateral sides as shown in FIG. 1B (e.g., also shown along the right-hand side in FIG. 1 above). As further shown in FIG. 1B, the first metal level 108 can include structural features that extend near the outlying 168, for example, to provide structural rigidity to the electronic device 100 and mitigate die and/or wafer bowing or warpage during manufacturing and can also provide a structure that mitigates crack propagation, for example, during die singulation or separation (e.g., saw cutting, etc.).

The connection ends of the spiral windings 171 and 172 are connected to respective ones of the terminals T1-T4 of the pad metal layer 118 by corresponding conductive vertical interconnects 124 (e.g., metal vias, side views of which are shown in FIG. 1 above). In the illustrated example, a conductive first vertical interconnect 124 is connected between a first end of the first spiral winding 171 of the thin-film resistor layer 123 and the first resistor terminal T1 of the pad metal layer 118, and a conductive second vertical interconnect 124 is connected between a second end of the first spiral winding 171 of the thin-film resistor layer 123 and the second resistor terminal T2 of the pad metal layer 118 (e.g., FIGS. 1C and 1D). FIGS. 1C and 1D show connection of the first end of the second spiral winding 172 of the thin-film resistor layer 123 to the third resistor terminal T3 by a corresponding conductive vertical interconnect 124. FIGS. 1F and 1G further show connection of a second end of the second spiral winding 172 to the fourth terminal T4 by a corresponding conductive vertical interconnect 124 (FIG. 1G).

In the illustrated example of FIGS. 1B-1G, the individual dummy resistive layer lines 174-177 are connected to a respective one of the resistor terminals T1-T4 by corresponding vias or vertical interconnects 124 that extend from the pad metal layer 118 to the TFR layer 123. The upper outer dummy resistive layer line 174 of the thin-film resistor layer 123 in this example is connected by a corresponding vertical interconnect to the first resistor terminal T1 (vertical interconnect not shown in FIG. 1B), and the example upper outer dummy resistive layer line 174 extends proximate to the fourth resistor terminal T4, but is not connected to the fourth resistor terminal T4 as shown in FIG. 1G (e.g., no corresponding vertical interconnect between the thin-film resistor layer 123 and the pad metal layer 118 at this location). The lower outer dummy resistive layer line 175 of the thin-film resistor layer 123 is connected by a corresponding vertical interconnect 124 to the fourth terminal T4 as shown in FIG. 1G. The dummy resistive layer line 175 extends proximate to the first resistor terminal T1 but is not connected to the first resistor terminal T1 (e.g., no vertical interconnect at this location).

The upper interior or inner dummy resistive layer line 176 of the thin-film resistor layer 123 is connected by a corresponding vertical interconnect 124 to the third resistor terminal T3 as shown in FIG. 1E. The upper inner dummy resistive layer line 176 extends proximate to the second resistor terminal T2, but the dummy resistive layer line 176 is not connected to the second resistor terminal T2 as shown in FIG. 1D (e.g., no corresponding vertical interconnect between the thin-film resistor layer 123 and the pad metal layer 118 at this location). The lower interior dummy resistive layer line 177 of the thin-film resistor layer 123 is connected by a corresponding vertical interconnect 124 to the second resistor terminal T2 as shown in FIG. 1D. The lower interior dummy resistive layer line 177 in this example extends proximate to the third resistor terminal T3, but the dummy resistive layer line 177 is not connected to the third resistor terminal T3 as shown in FIG. 1E (e.g., no corresponding vertical interconnect between the thin-film resistor layer 123 and the pad metal layer 118 at this location).

The selective connection of the inner and outer dummy resistive layer lines 174-177 to only one of two associated resistor terminals T1-T4 allows the dummy resistive layer lines 174-177 to operate as a shield connected at only one end, with the inner and outer dummy resistive layer lines 174-177 operating to be adjacent to the first or last spiral winding line. The dummy resistive layer lines 174-177 in the illustrated example have the same nominal line widths and pitch spacing from the nearest resistive layer line of the spiral windings, and beneficially ensure that all current carrying resistive layer lines 123 of the spiral windings 171 and 172 are aligned with two neighboring resistive layer lines or one neighboring resistive layer line 123 and a neighboring dummy resistive layer line 174-177.

Moreover, during manufacturing, the dummy resistive layer lines 174-177 can help segment-to-segment matching of the lateral line widths of the current carrying segments of the spiral windings 171 and 172. Because the outermost spiral resistive line is semi-isolated, e.g., there is a neighboring resistive line only on one side of it, loading effects during fabrication etching can cause a non-uniform linewidth compared to interior, non-isolated resistive lines with neighbors on both sides.

Providing the extended dummy resistive layer lines 174-177 can help improve line width uniformity and resistance matching for the thin-film resistor network segments that carry current. The dummy resistive layer lines 174-177 can also help lower the local electric field and improve high voltage breakdown capability of the spiral windings of the resistors 170, particularly for small radius of curvature areas (e.g., in the turn portions of the spiral windings 171 and/or 172).

The spiral wound arrangement of the thin-film resistors 170 can help to improve high voltage performance, particularly compared to serpentine windings structures (e.g., FIG. 1A above). The spiral designs help mitigate or avoid features with small radius of curvature that can elevate the local electric field, and the higher radius of curvature associated with the spiral winding configurations mitigates the need for underlying metal switchbacks or turnaround features in the pad metal layer 118 and associated connection vias (e.g., vertical interconnects 124) while maintaining high voltage operation performance advantages and better surge performance compared with metal shielded counterparts. The spiral design facilitates providing the spiral windings 171 and/or 172 above a gap in the underlying pad metal layer 118, which can help reduce the resistor size.

FIGS. 1H-1N show another example including multiple spaced apart spiral wound thin-film resistors in a snail shaped spiral thin-film resistor circuit with spiral co-wound thin-film resistors. This example includes a multilevel metallization structure having a dielectric layer 116 over a semiconductor layer 102, a pad metal layer 118 on the dielectric layer 116, and a thin-film resistor layer 123 located over the pad metal layer 118, for example, as described above. The snail shaped configuration of FIGS. 1H-1N can be included alone or in combination with other types and forms of thin-film resistors (e.g., as described above) in various implementations. This example has co-wound spiral resistors 170 (schematically labeled R1A and R1B in FIG. 1H) in a first interleaved spiral structure of the TFR layer 123 as well as a second interleaved spiral structure that is spaced apart from the first interleaved spiral structure and includes co-wound interleaved resistors 180 (schematically labeled R2A and R2B in FIG. 1H) forming two resistor divider circuits with resistor terminals T1A, T1B, T2A, T2B, T3A, and T3B.

As shown in FIGS. 1H-1N, the resistor terminals T1A, T1B, T2A, T2B, T3A, and T3B of the pad metal layer 118 can be contacted by bond wires or other suitable connections through openings 168 in the upper metallization layers (e.g., openings in 120, 122, 126, 128, and 129 in FIG. 1 above). A similar gap 168 can extend around the lateral sides as shown in FIG. 1H (e.g., also shown along the right-hand side in FIG. 1 above). As further shown in FIG. 1H, the first metal level 108 can include structural features that extend near the outlying 168, for example, to provide structural rigidity to the electronic device 100 and mitigate die and/or wafer bowing or warpage during manufacturing and can also provide a structure that mitigates crack propagation, for example, during die singulation or separation (e.g., saw cutting, etc.).

The resistors 170 and 180 in FIGS. 1H-1N are constructed in the multilevel metallization structure as described above in connection with FIG. 1 with the patterning and sizing of the resistive layer 123, the pad metal layer 118, the SO bilayer 114, 116 corresponding to the top views of FIGS. 1B-1G. The resistive layer 123 is sealed and located on the first sublayer 122 of the dielectric seal structure, with the second sublayer 126 of the dielectric seal structure located on the resistive layer 123 as described above. The resistive (TFR) layer 123 is spaced apart from the semiconductor layer 102 in one example by the spacing distance 145 (FIG. 1) of approximately 9.0 μm or more and approximately 29 μm or less, such as approximately 19 μm, with the pad metal layer 118 located above the top surface of the semiconductor layer 102. In addition, the gap G (FIG. 1) in the dielectric layer 116 extends between the resistor terminals T1A, T1B, T2A, T2B, T3A, and T3B and the same or a similar gap is provided in the dielectric layer 116 between the resistor terminals in one example.

The resistor terminals T1A, T1B, T2A, T2B, T3A, and T3B are connected to the resistor features of the TFR layer 123 by corresponding vertical interconnects 124 (e.g., FIGS. 1J, 1L and 1N). The resistive layer 123 is sealed and located on the first sublayer 122 of the dielectric seal structure, with the second sublayer 126 of the dielectric seal structure located on the resistive layer 123. In addition, the resistive layer 123 is spaced apart from the semiconductor layer 102 in one example by the spacing distance 145 (FIG. 1), with the pad metal layer 118 located above the top surface of the semiconductor layer 102. In addition, the gap G (FIG. 1) in the dielectric layer 116 extends between the first and second resistor terminals and the same or a similar gap is provided in the dielectric layer 116 between the resistor terminals in one example.

The thin-film resistors 170 are co-wound in the first spiral arrangement with interleaved spiral windings 171 of a first resistor (R1A) and 172 of a third resistor (R1B) in adjacent pairs 173 (FIG. 1L) formed in the TFR layer 123. The thin-film resistors 180 are co-wound in the second spiral arrangement with interleaved spiral windings 181 of a second resistor (R2A) and 182 of a fourth resistor (R2B) formed in the TFR layer 123. In the example of FIGS. 1H-1N, the first resistor terminal T1A is inside an inner extent of the first spiral winding 171, the second resistor terminal T2A is outside the outer extents of the first and second spiral windings 171 and 181, and the third resistor terminal T3A is inside an inner extent of the second spiral winding 181. The spiral windings 171, 181, 172 and 182 of the thin-film resistor layer 123 in FIGS. 1H-1N overlie respective gaps in the pad metal layer 118.

The first thin-film resistor 170 (e.g., R1A in FIG. 1H) has a first spiral winding 171 of the thin-film resistor layer 123 with multiple turns in the thin-film resistor layer 123. The first spiral winding 171 is connected between the first and second resistor terminals T1A and T2A of the pad metal layer 118 (FIGS. 1H, 1K, 1L, 1M and 1N) by corresponding vertical interconnects 124 (FIGS. 1L and 1N).

The second thin-film resistor 180 of the second spiral arrangement (e.g., R2A in FIG. 1H) is spaced apart from the first thin-film resistor 170 and has a second spiral winding 181 with multiple turns in the thin-film resistor layer 123. The second spiral winding 181 is connected between the second resistor terminal T2A and the third resistor terminal T3A of the pad metal layer 118 (FIGS. 1H, 1I, and 1N) by corresponding vertical interconnects 124, one of which is shown in FIG. 1N. The first and second resistors (R1A and R2A) are connected in series with one another to form a resistor divider circuit and are both connected to the second terminal T2A by a single shared vertical interconnect 124 as shown in FIG. 1N.

In one example, the first and second spiral windings 171 and 181 are of approximately equal line widths in the TFR layer 123. In the illustrated example, the first spiral winging 171 of the first resistor R1A has a longer overall length and more spiral turns to provide a higher resistance than the second resistor R2A. This facilitates high voltage sensing with the first terminal T1A connected to a high voltage node with the voltage across the first resistor R1A greater than the voltage across the second resistor R2A, and the voltage at the second resistor terminal T2A significantly lower than the high voltage node.

The illustrated example includes a second resistor divider circuit formed by series connected third and fourth resistors 170 and 180 (labeled R1B and R2B, respectively, in FIG. 1H). The third thin-film resistor 170 (e.g., R1B in FIG. 1H) has a third spiral winding 172 of the thin-film resistor layer 123 with multiple turns in the thin-film resistor layer 123. The third spiral winding 172 is connected between the fourth and fifth resistor terminals T1B and T2B of the pad metal layer 118 (FIGS. 1H, 1K, 1M and 1N) by corresponding vertical interconnects 124 (FIG. 1N). In addition, the turns of the third spiral winding 172 are interleaved (e.g., co-wound) with the turns of the first spiral winding 171, which may be beneficial for resistor matching.

The fourth thin-film resistor 180 of the fourth spiral arrangement (e.g., R2B in FIG. 1H) is spaced apart from the third thin-film resistor 170 (R1B) and has a fourth spiral winding 182 with multiple turns in the thin-film resistor layer 123. In addition, the turns of the fourth spiral winding 182 are interleaved (e.g., co-wound) with the turns of the second spiral winding 181 (e.g., FIG. 1J), which may be beneficial for resistor matching. The fourth spiral winding 182 is connected between the fifth resistor terminal T2B and the sixth resistor terminal T3B of the pad metal layer 118 (FIGS. 1H, 1I, 1J, and 1N) by corresponding vertical interconnects 124 (FIGS. 1J and 1N). The third and fourth resistors (R1B and R2B) are connected in series with one another to form a second resistor divider circuit and are both connected to the fifth resistor terminal T2B by a single shared vertical interconnect 124 as shown in FIG. 1N.

In one example, the third and fourth spiral windings 172 and 182 are of approximately equal line widths in the TFR layer 123. In the illustrated example, the third spiral winging 172 of the third resistor R1B has a longer overall length and more spiral turns to provide a higher resistance than the spiral winding 182 of the fourth resistor R2B to facilitate high voltage sensing with the fourth resistor terminal T1B connected to a high voltage node. In this configuration, the voltage across the third resistor R1B will be greater than the voltage across the fourth resistor R2B, and the voltage at the fifth resistor terminal T2B will be lower than the high voltage node. In the example of FIGS. 1H-1N, the fourth resistor terminal T1B is inside an inner extent of the third spiral winding 172, the fifth resistor terminal T2B is outside the outer extents of the respective third and fourth spiral windings 172 and 182, and the sixth resistor terminal T3B is inside an inner extent of the fourth spiral winding 182.

The respective spiral windings 171, 172, 181 and 182 include only curved portions of the thin-film resistor layer 123 (e.g., having no straight or linear portions other than the terminal connection feeds as shown in FIGS. 1H-1N). In another implementation, some or all of the spiral windings 171, 172, 181 and 182 can include both straight and turn portions of the thin-film resistor layer 123. The illustrated co-wound interleaved example of FIGS. 1H-1N provides two spaced apart, generally circular winding shapes that form a co-wound, interleaved snail design as shown in FIG. 1H, although not a requirement of all possible implementations.

The example of FIGS. 1H-1N also has electrically inactive dummy resistive layer lines 174, 176, 177, 184, 186, and 187 of the thin-film resistor layer 123 that are positioned adjacent to and spaced apart from a first or last turn of the spiral windings 171, 172, 181, and/or 182. In the illustrated example, the spiral windings 171 and 172 are surrounded by an outer dummy resistive layer line structure 174 and upper and lower interior or inner dummy resistive layer lines 176 and 177, respectively (FIGS. 1H, 1K, and 1L). The inner dummy resistive layer lines 176 and 177 provide dummy resistive layer line gaps at the connections of the spiral windings 171 and 172 to the respective terminals T1A and T1B (e.g., FIG. 1L) and the inner dummy resistive layer lines 176 and 177 are at least partially surrounded by an inner extent of the spiral windings 171 and 172. The outer dummy resistive layer line 174 extends around the outer extent of the spiral windings 171 and 172 (e.g., FIG. 1H) and continues to the resistive divider joining connections as shown in FIGS. 1M and 1N to the resistor terminal T2B by a corresponding vertical interconnect (FIG. 1N).

The illustrated example of FIGS. 1H-1N also includes an outer dummy resistive layer line 184 that extends around the outer extent of the spiral windings 181 and 182 (e.g., FIGS. 1H-1J, 1M, and 1N) and continues to the resistive divider joining connections as shown in FIGS. 1M and 1N to the resistor terminal T2A by a corresponding vertical interconnect (FIG. 1N). In addition, the spiral windings 181 and 182 are surrounded by upper and lower interior or inner dummy resistive layer lines 186 and 187, respectively (FIGS. 1H-1J) with the upper interior dummy resistive layer line 186 connected to the resistor terminal T3B by a corresponding vertical interconnect 124 (FIG. 1J) and the dummy resistive layer line 187 connected to the resistor terminal T3A by a corresponding vertical interconnect (not numerically designated in FIG. 1I).

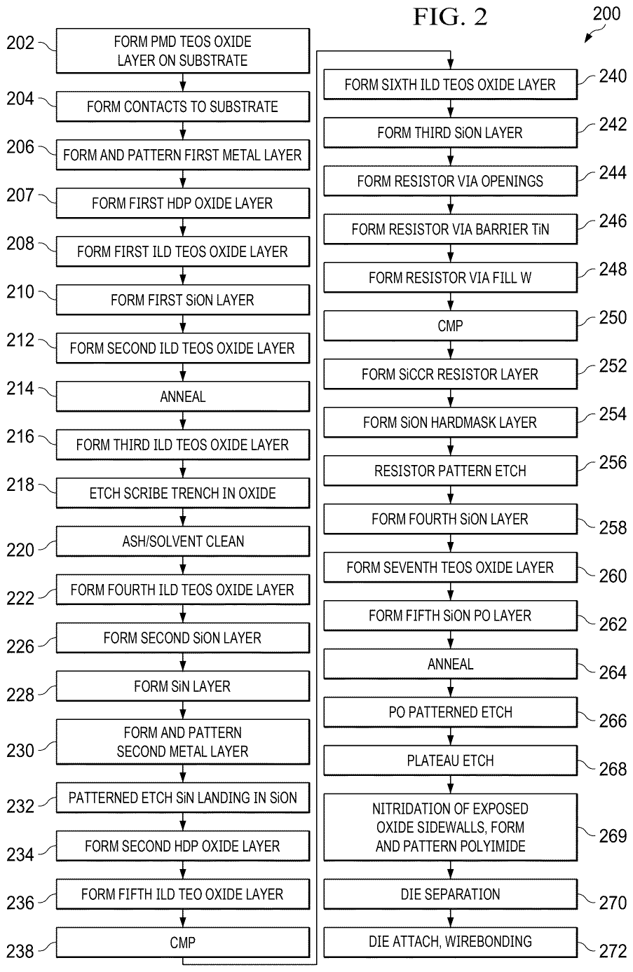

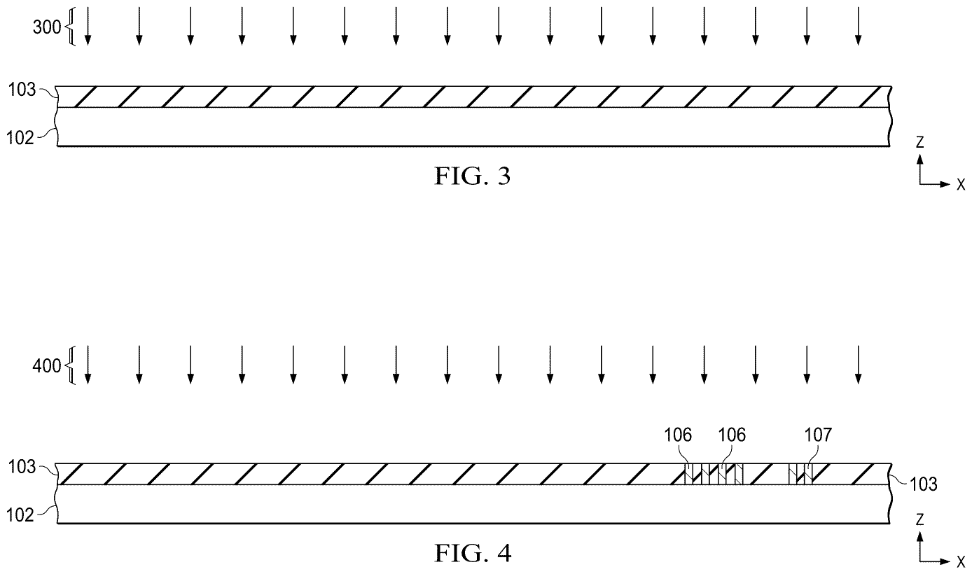

Referring also to FIGS. 2-36, FIG. 2 shows a method 200 of fabricating an electronic device, such as an integrated circuit, and FIGS. 3-36 show the integrated circuit 100 FIGS. 1 and 1A undergoing fabrication processing according to the method 200. The described steps may concurrently be used to fabricate and interconnect other electronic circuits and/or components (e.g., transistor circuits, other isolation circuits, etc.) in a single semiconductor die. The metallization structure in one example includes metal lines, cylindrical contacts and vias and/or trench contacts and vias that electrically couple terminals of the thin-film resistor R1 to one or more internal components (e.g., the second resistor R2 in the resistive divider circuit example described above).

The method 200 can include front end processing (not shown), for example, to fabricate one or more circuit components (e.g., transistors, etc.) on and/or in a starting wafer (e.g., on and/or in the semiconductor layer 102 above). In one example, the front-end processing includes processing of a starting semiconductor wafer, such as a p-type silicon wafer, an SOI structure with a silicon layer, a silicon-germanium layer, or another layer having semiconductor material and can include forming isolation structures, such as shallow trench isolation (STI) structures (not shown) on and/or in a top side of the semiconductor layer 102.

The method 200 includes fabricating a metallization structure over the semiconductor layer 102 including forming a pre-metal dielectric layer at 202. FIG. 3 shows one example of the processing at 202, in which a deposition process 300 is performed that deposits the PMD layer 103 (e.g., SiO₂) on the semiconductor layer 102. In one example, the process 300 deposits silicon dioxide to form the PMD layer 103 to a thickness of approximately 2.9 μm.

The method 200 continues at 204 in FIG. 2 with forming contacts (e.g., contacts 106 and 107) through the PMD layer 103. FIG. 4 shows one example, in which a contact formation process 400 is performed that forms contacts 106 and peripheral contacts 107 through the PMD layer 103 and on the semiconductor layer 102. In one example, the process 400 includes patterned etching (not shown) to form cylindrical holes and/or trenches for the respective contacts, and one or more deposition steps that deposit suitable metal (e.g., that is or includes tungsten) in the openings, followed by a planarization step (e.g., chemical mechanical polishing or CMP) to provide a planar top side of the PMD layer 103 and the formed respective contacts 106 and 107. In one example, the contacts 107 are formed at 204 in regions near the outer periphery of the illustrated portion to provide protection against cracks and mechanical stress on the integrated circuit 100 as well as provide a barrier against ingress from external ionic contamination at the die edge, although not a strict requirement of all possible implementations.

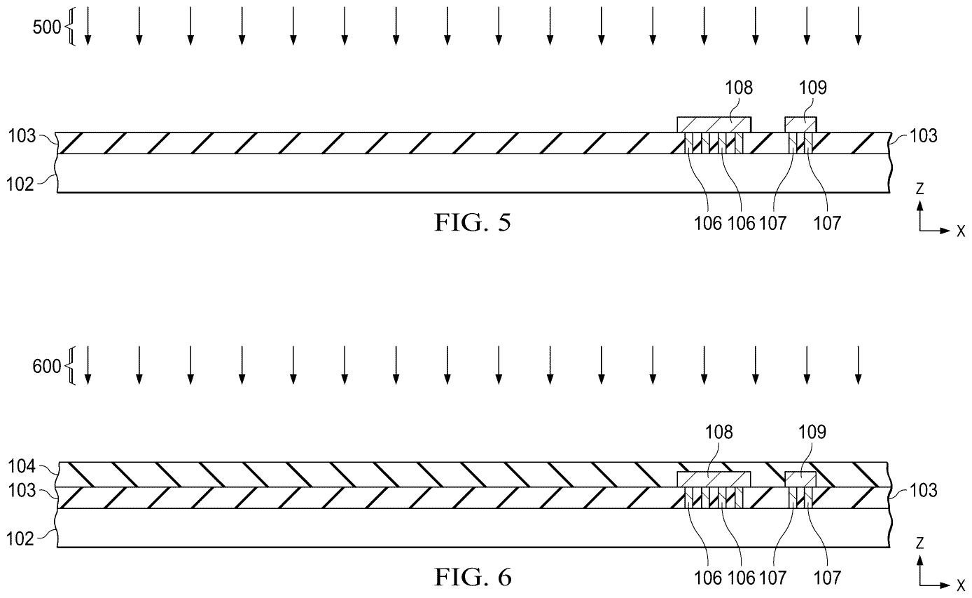

The method 200 continues at 206 in FIG. 2 with forming the first metallization structure level over the PMD layer 103. The first metallization level includes the metal features 108 and 109 on the respective contacts 106 and 107. FIG. 5 shows one example, in which a process 500 is performed that deposits a conductive metal layer on the PMD layer 103 (e.g., aluminum to a thickness of approximately 3.0 μm), and etches exposed portions of the deposited metal using a patterned etch mask (not shown) to form the conductive metal grounded fill feature 108 and peripheral conductive metal seal structure 109. The method 200 in one example further includes forming a first high density plasma (HDP) oxide layer at 207.

At 208 in FIG. 2, the first ILD layer 104 is deposited on the PMD layer 103. FIG. 6 shows one example, in which a process 600 is performed that deposits and planarizes the first ILD layer 104 on the PMD layer 103. In one example, the process 600 is a plasma enhanced chemical vapor deposition (PECVD) deposition process that forms a silicon dioxide layer as a tetraethyl orthosilicate (e.g., tetraethoxysilane or TEOS oxide) ILD layer 104 to a thickness over the first metal layer features of approximately 1.4 μm and a thickness over the PMD layer 103 of approximately 3.0 to 4.4 μm following planarization by chemical mechanical polishing (CMP).

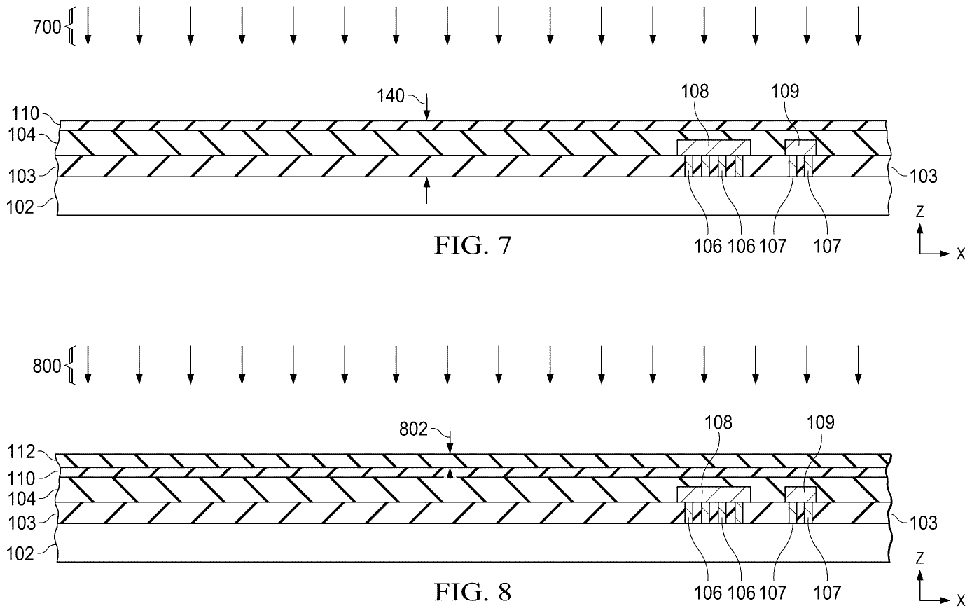

At 210 in FIG. 2, a first dielectric layer is formed over the first ILD layer 104. FIG. 7 shows one example, in which a deposition process 700 is performed that forms the dielectric layer 110 above (e.g., on and directly contacting) the first ILD layer 104. In one example, the dielectric layer 110 is or includes silicon oxynitride of any suitable stoichiometry (e.g., SiOxNy, such as SiON₃), and can be referred to as a first silicon oxynitride layer. In one example, the top surface of the dielectric layer 110 is spaced apart from the top side of the semiconductor layer 102 by the distance 140 of approximately 8.3 μm along the third direction Z.

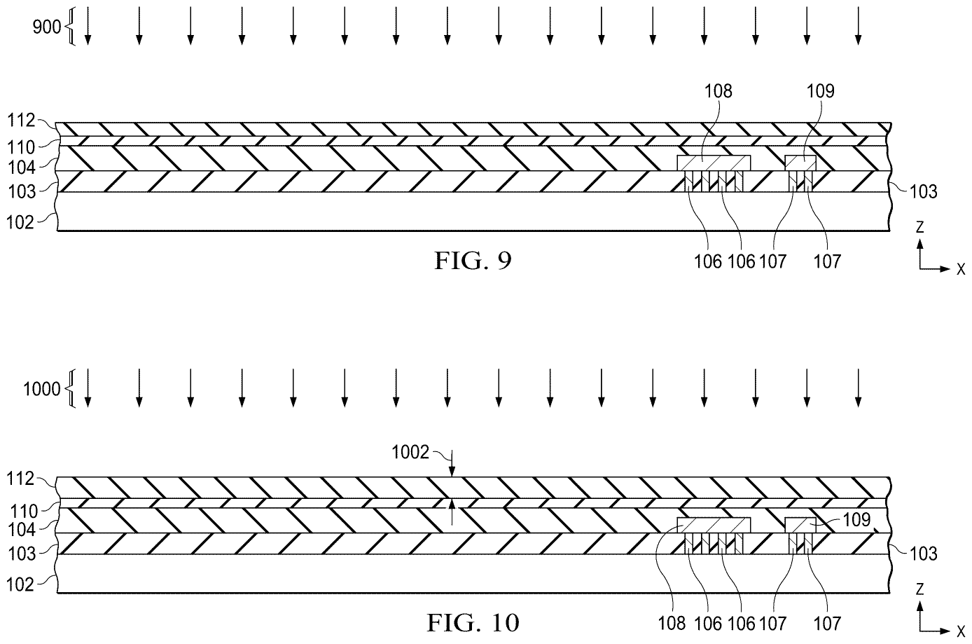

At 212 in FIG. 2, a second ILD layer is formed, for example, a second oxide dielectric layer over the dielectric layer 110. FIG. 8 shows one example, in which a PECVD deposition process 800 is performed that forms the second ILD layer 112 over (e.g., on and contacting) the top surface of the dielectric layer 110 to a thickness 802 of approximately 3.6 μm. At 214 in FIG. 2, a thermal process is performed, for example, to increase tensile strength of the first metal structures 108 and 109 for wafer bow compensation benefits. FIG. 9 shows one example, in which a thermal annealing process 900 is performed that anneals the structure. At 216 in FIG. 2, a further (e.g., third) TEOS oxide layer is formed. FIG. 10 shows one example, in which a PECVD process 1000 is performed that forms further TEOS silicon dioxide of the second ILD layer 112 to provide an increased thickness 1002.

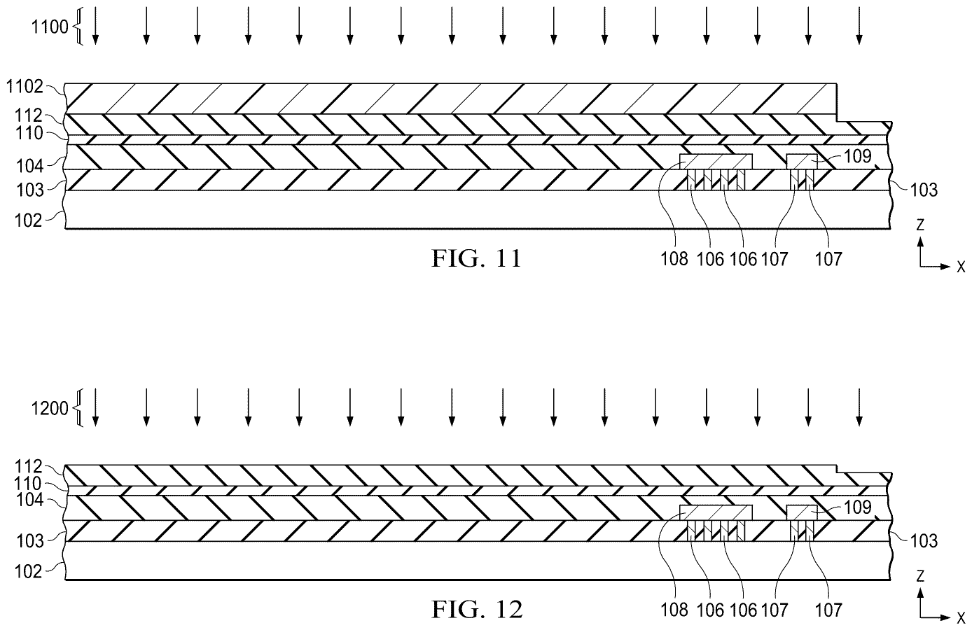

At 218 in FIG. 2, an etch process is performed to form a scribe trench in the second ILD layer 112. FIG. 11 shows one example, in which an etch process 1100 is performed using an etch mask 1102 to form a trench in an exposed peripheral portion of the second ILD layer 112, for example, to a depth of approximately 0.5 μm to create alignment marks for subsequent second-level metal patterning. In one implementation, the method 200 includes a post-etch cleaning process at 220 in FIG. 2. FIG. 12 shows one example, in which a post-etch ash/solvent clean/ash process 1200 is performed that cleans the top surface of the second ILD layer 112 including the etched trench.

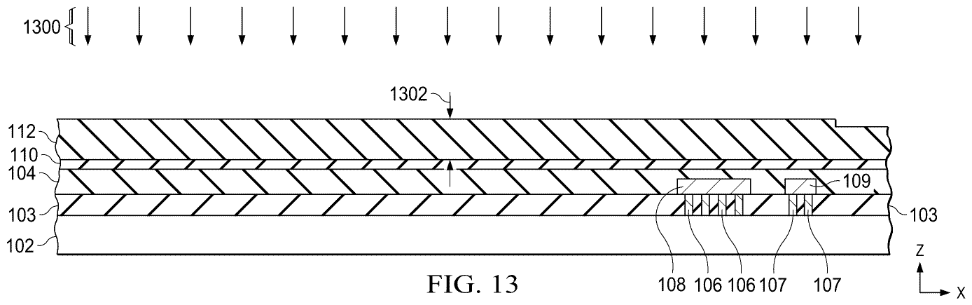

At 222 in FIG. 2, the thickness of the second ILD layer 112 is again increased in one example by depositing further silicon dioxide. FIG. 13 shows one example, in which another (e.g., fourth) TEOS oxide deposition process 1300 is performed that forms further TEOS silicon dioxide of the second ILD layer 112 to provide a final thickness 1302 of approximately 6.6 μm, with a contoured edge formed by the recently etched scribe trench.

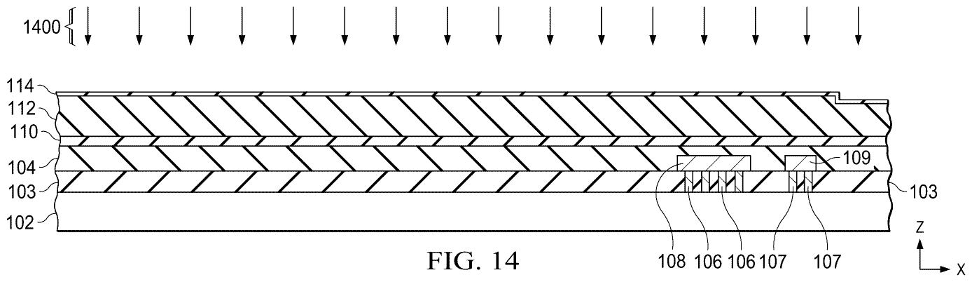

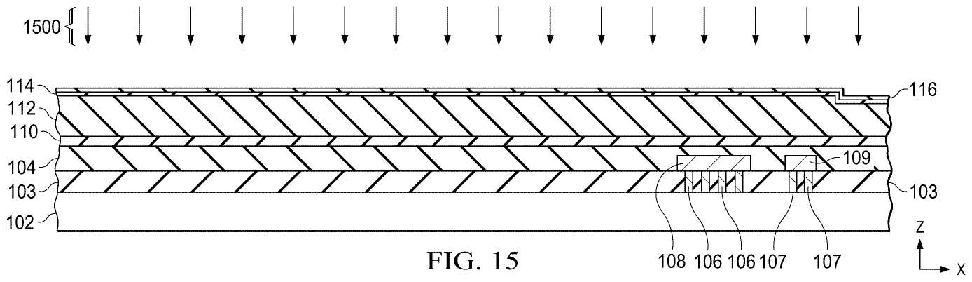

At 226 and 228 in FIG. 2, an SO bilayer is formed on the second ILD layer 112. At 226, another dielectric layer is formed above the second ILD layer 112. FIG. 14 shows one example, in which a deposition process 1400 is performed that forms the dielectric layer 114 over (e.g., on and contacting) the top surface of the second ILD layer 112, for example, to a thickness of approximately 0.3 to 0.5 μm. At 228 in FIG. 2, a silicon nitride layer is formed over the dielectric layer 114. FIG. 15 shows one example, in which a deposition process 1500 is performed that forms the dielectric layer 116 over (e.g., on and contacting) the top surface of the dielectric layer 114.

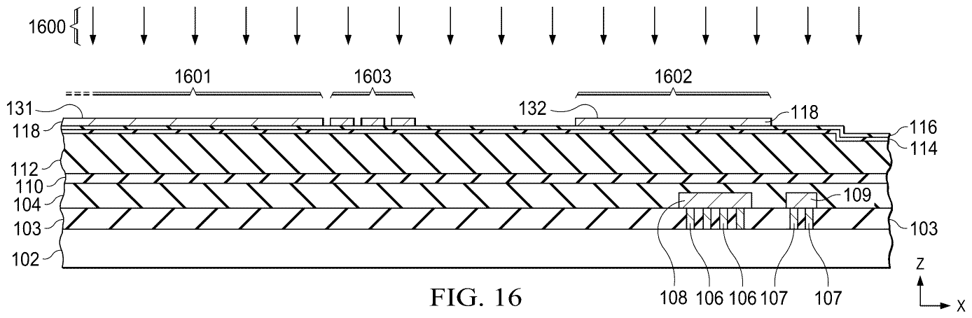

At 230 in FIG. 2, the second level conductive metal features are formed. FIG. 16 shows one example, in which a process 1600 is performed that deposits and patterns the features of the pad metal layer 118, including the resistor terminals 131-133 described above, where the third resistor terminal 133 is not shown in the section view of FIG. 16. The process 1600 in one example includes deposition of an aluminum layer and selective etching of the deposited aluminum to form a first patterned metal feature 1601 that includes the first resistor terminal 131, a second patterned metal feature 1602 that includes the second resistor terminal 132, and further patterned metal features 1603 that can provide the turnaround end portions of the serpentine first resistor R1 in the pad metal layer 118 as described above in connection with FIG. 1A in the section view of FIG. 16. In one example, the deposited aluminum layer can include titanium (Ti) and titanium nitride (TiN), such as Ti/TiN barriers under and above the aluminum, for example, deposited in-situ on the same plasma vapor deposition (PVD) tool (not shown).

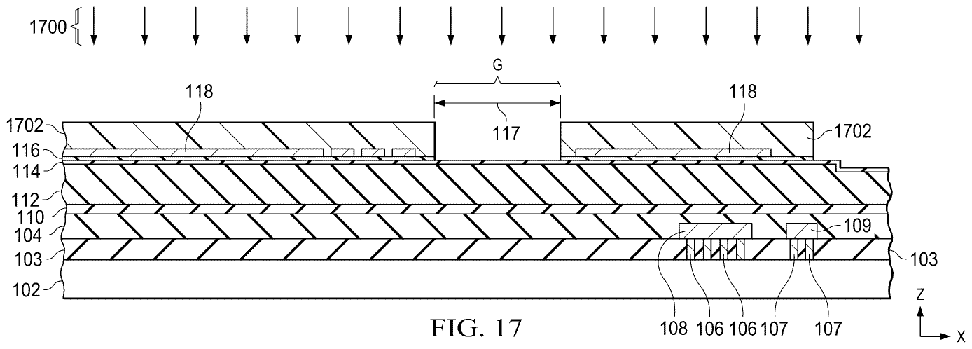

The method 200 continues at 232 in FIG. 2 with selective etching of the SO bilayer 114, 116. FIG. 17 shows one example, in which an etch process 1700 is performed using an etch mask 1702 to etch the exposed portion of the dielectric layer 116 to form the SO relief (SOR) gap G with the gap distance 117, where the SO bilayer 114, 116 has a discontinuity in the interface between the layers 114 and 116 along the gap distance 117 of the gap G. In one example, the first opening in the etch mask 1702 provides a gap distance 117 of approximately 5.0 μm or more. In one example, the etch mask 1702 has another opening (e.g., on the right side of FIG. 17) to start etching near the prospective die boundary to reduce the burden on the subsequent plateau etch (e.g., at 268 in FIG. 2) to etch down to below the surface of the first metal layer feature 109. In one implementation, a cleaning step is included in the process 1700, such as an ash/solvent clean, and the process 1700 in one example removes the exposed SiN layer 116 and lands in the SiON dielectric layer 114 to leave the remaining thickness of the dielectric layer 114 of approximately 0.25 μm or more within the SOR gap G. In another example, the process 1700 can optionally etch fully through the SiON dielectric layer 114. Stopping in the SiON dielectric layer 114 may facilitate subsequent planarization (e.g., CMP) of metal overlying the second ILD layer 112.

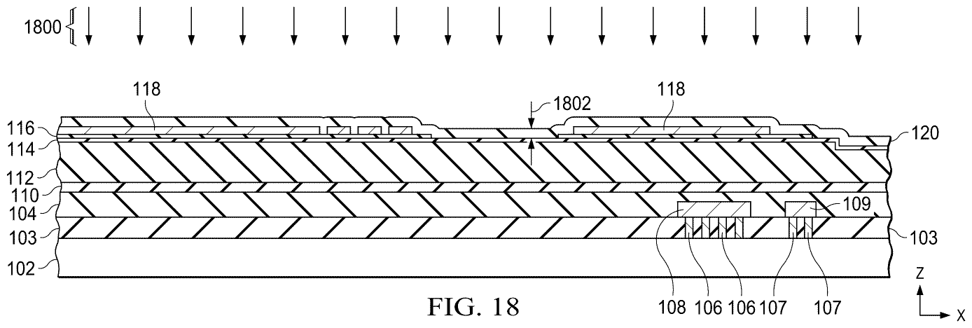

At 234-240 in FIG. 2, the third ILD layer 120 is formed over (e.g., on and directly contacting) the patterned features of the pad metal layer 118 and the top surfaces of the silicon dielectric layer 116 and the dielectric layer 114 in the gap G of the dielectric layer 116. At 234, a high density plasma (HDP) oxide deposition is performed. FIG. 18 shows one example, in which an HDP deposition process 1800 is performed that deposits silicon dioxide to form a first portion of the third ILD layer 120 on the patterned features of the pad metal layer 118 and the top surfaces of the dielectric layer 116 and the dielectric layer 114 in the gap G of the dielectric layer 116. The HDP process 1800 in one example forms the initial silicon dioxide to a thickness 1802 of approximately 0.6 μm.

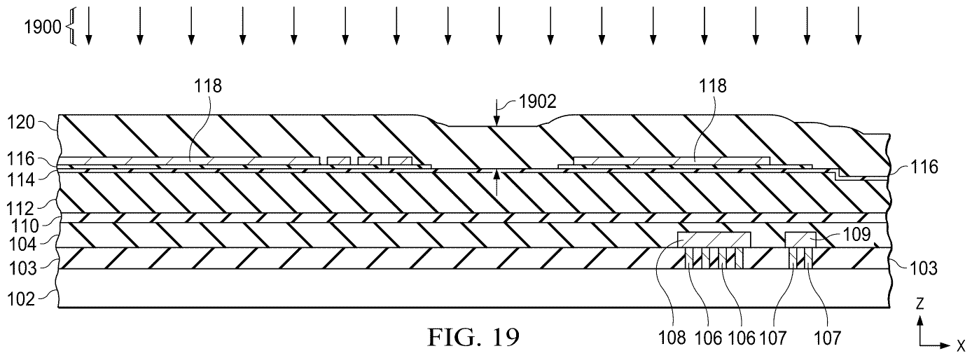

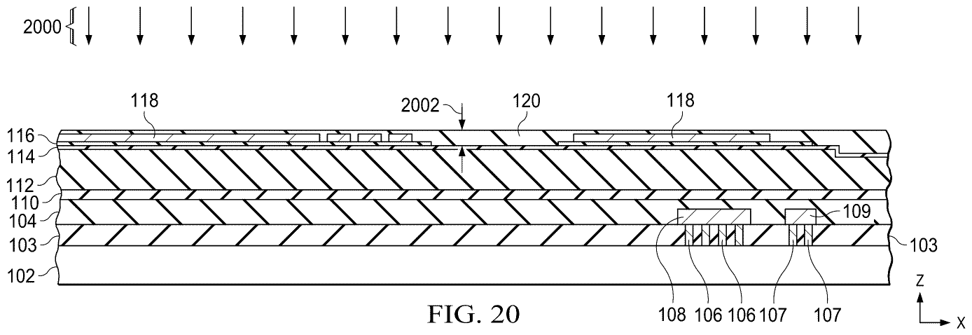

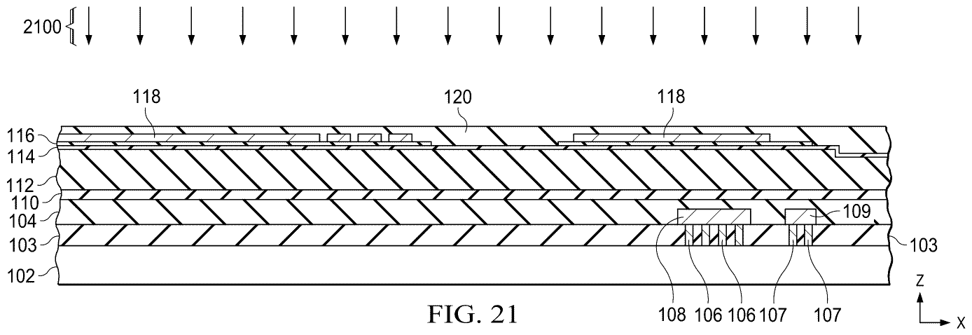

At 236 and FIG. 2, another oxide deposition is performed to increase the thickness of the third ILD layer 120. FIG. 19 shows one example, in which a PECVD process 1900 is performed that deposits TEOS silicon dioxide as a dielectric layer to a thickness 1902 including the HDP oxide of approximately 3.3 μm. At 238 in FIG. 2, the method 200 in one example also includes a planarization step (e.g., CMP). FIG. 20 shows one example, in which a CMP process 2000 is performed that planarize is the top surface of the third ILD layer 120 to provide a third ILD layer thickness 2002 of approximately 2.8 μm. At 240 in FIG. 2, the method 200 continues with forming a further (e.g., sixth) TEOS silicon dioxide of the third ILD layer 120. FIG. 21 shows one example, in which another PECVD deposition process 2100 is performed that deposits a further TEOS oxide, for example, to add an additional 0.5 μm to the thickness of the third ILD layer 120.

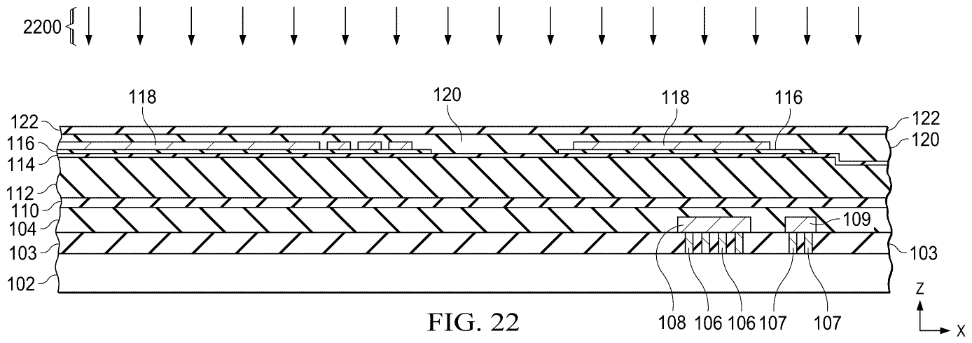

At 242 in FIG. 2, a bottom sub-layer (e.g., the dielectric layer 122 in FIG. 1 above) of a hermetic seal structure is formed over (e.g., on and directly contacting) the top surface of the third ILD layer 120. FIG. 22 shows one example, in which a deposition process 2200 is performed that deposits the dielectric layer 122 (e.g., a silicon oxynitride layer) of any suitable stoichiometry and thickness over the third ILD layer 120.

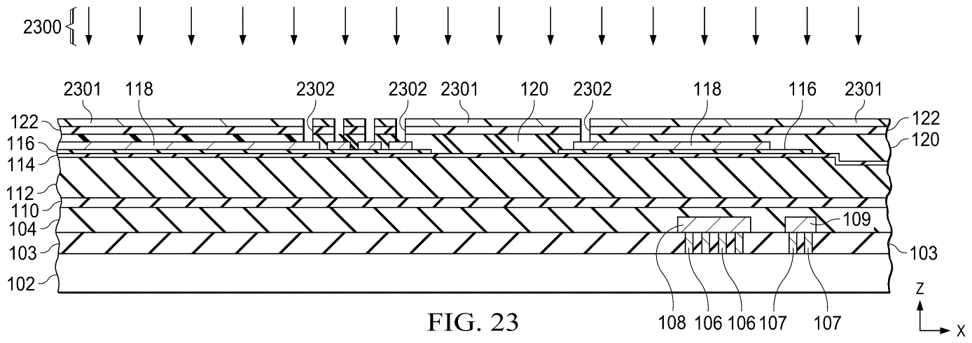

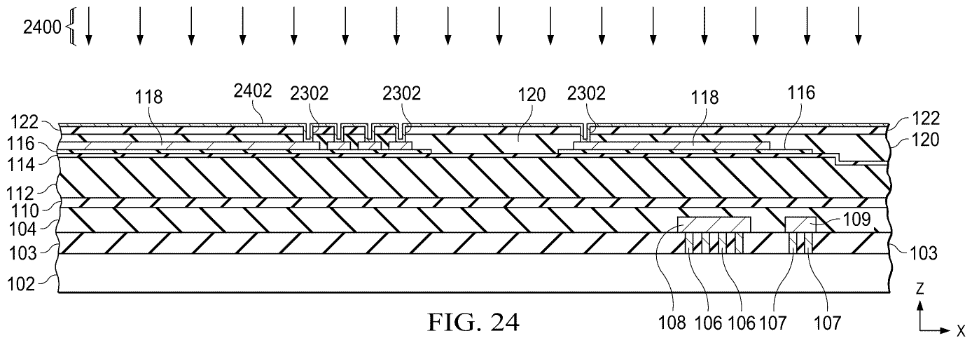

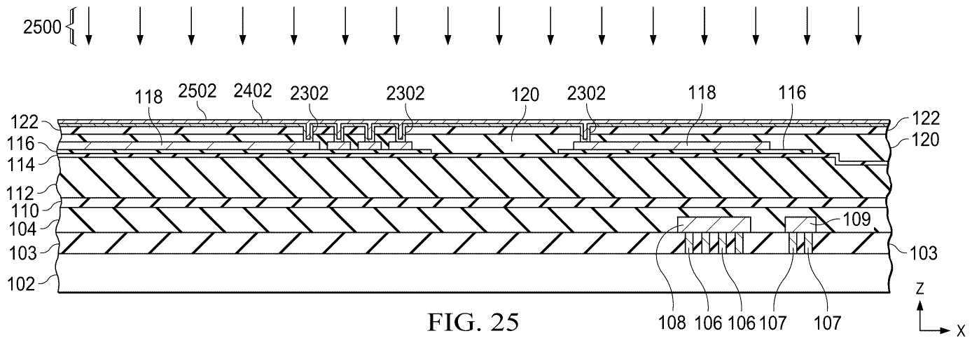

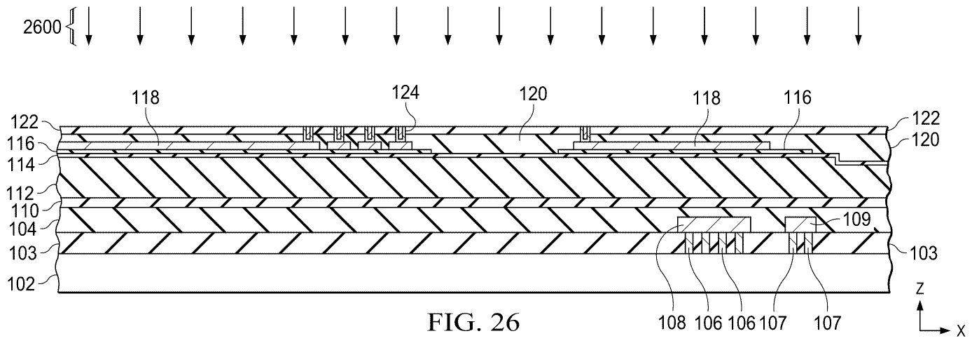

At 244-250 in FIG. 2, conductive metal vias or contacts are formed through the third layer 122 and the third ILD layer 120 to form connections to patterned features of the pad metal layer 118, including two vertical interconnects 124 (e.g., vias) dropping down to each metal turnaround 1603 for the two respective TFR segments connected to it. The vertical interconnects 124 also provide terminal connection routing between the TFR layer 123 and the pad metal layer 118 (e.g., FIGS. 1D, 1E, 1G, 1J, 1, and 1N). The contact formation includes forming resistor contact via openings at 244 in FIG. 2. FIG. 23 shows one example, in which an etch process 2300 is performed using an etch mask 2301 to form resistor contact via openings 2302 through the dielectric layer 122 and the third ILD layer 120, for example, cylindrical or square openings of approximately 0.4 μm×0.4 μm of via pairs spaced by approximately 0.4 μm. In one example, the processing 2300 includes etching and post etch cleaning steps. At 246 in FIG. 2, a resistor via barrier metal is formed in the resistor contact via openings 2302. FIG. 24 shows one example, in which a deposition process 2400 is performed that deposits titanium nitride 2402 (TiN) in the openings 2302 and on the top side of the dielectric layer 122. At 248 in FIG. 2, the method 200 continues with filling the contact via openings with conductive metal. FIG. 25 shows one example, in which a deposition process 2500 is performed that deposits tungsten 2502 or other suitable conductive metal on the titanium nitride 2402 in the openings 2302. At 250 in FIG. 2, the structure is planarized (e.g., by CMP) to remove metals from the field between vias. FIG. 26 shows one example, in which a CMP process 2600 is performed that removes titanium nitride 2402 and tungsten 2502 from the top side of the dielectric layer 122, leaving the remaining resistor contact vias to provide conductive vertical interconnects 124 for electrical connection from the resistor terminals of the pad metal layer 118 to subsequently formed thin-film resistors. In one example, the process 2600 further includes a 50 Å oxide etch sputter clean to remove any remnant tungsten oxide (WₓO_{y}) from the surface of the tungsten plugs.

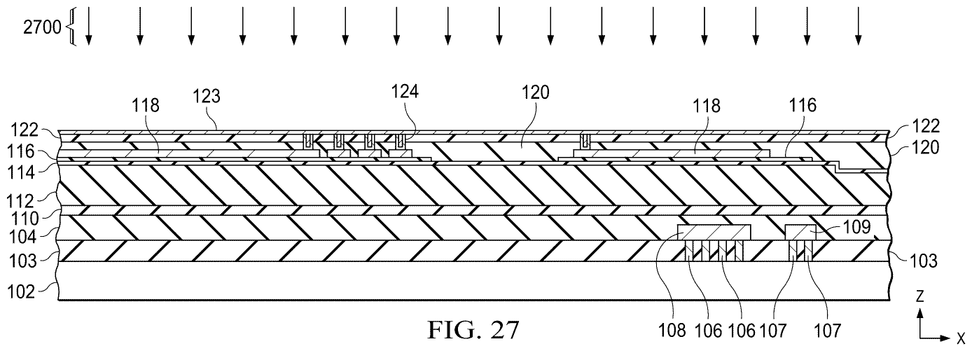

At 252-256 in FIG. 2, the thin-film resistors are formed. At 252, a resistor film layer is formed. FIG. 27 shows one example, in which the TFR layer 123 is deposited to any suitable thickness using a deposition process 2700. In one example, the TFR layer 123 is or includes silicon and chromium. In one implementation, the TFR layer 123 is or includes SiCr of any suitable stoichiometry and thickness. In another implementation, the TFR layer 123 is or includes silicon, chromium, and carbon, such as SiCCr of any suitable stoichiometry and thickness (e.g., approximately 32 Å).

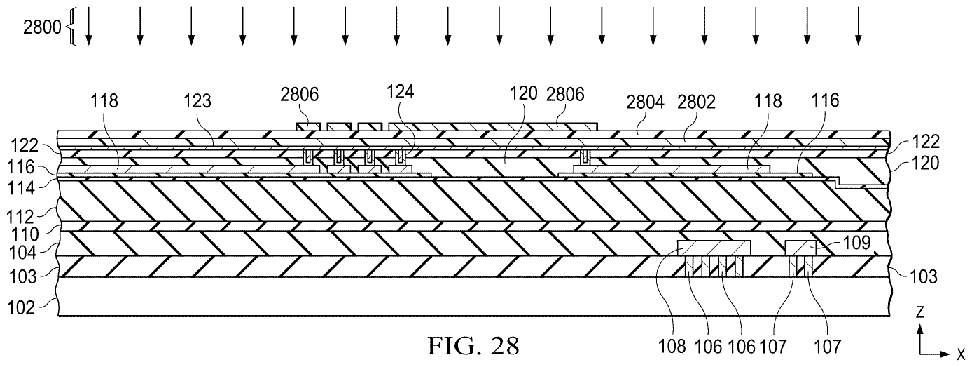

At 254 in FIG. 2, a protective layer is formed for patterning the TFR layer 123. FIG. 28 shows one example, in which a protective layer deposition and patterning process 2800 is used to pattern a protective layer 2802 over the regions where the thin-film resistors will be formed. In the illustrated example, the protective layer 2802 is or includes silicon oxynitride of any suitable thickness and stoichiometry (e.g., approximately 300 Å) over the wafer. In one implementation, a bottom antireflective coating (BARC) layer (not shown) is then applied over the entire wafer, and a photoresist layer (not shown) is formed over the BARC layer and patterned. In this example, an etch is performed to remove the BARC layer and the protective mask except under the photoresist and BARC under the resist, and then to selectively remove the exposed portions of the TFR layer 123 in the exposed regions of the TFR layer 123, after which the photoresist and remaining BARC are removed. The protective layer 2802 can help to mitigate or prevent the photoresist strip process from chemically modifying the TFR resistor. In one example, the TFR layer 123 is transparent to optical wavelengths used to pattern the photoresist and may be subject to pattern variability from underlying metal reflections without the use of the BARC layer. Thus, the BARC layer or other suitable photolithographic light transmission blocking layer can be used to facilitate precise linewidth control.

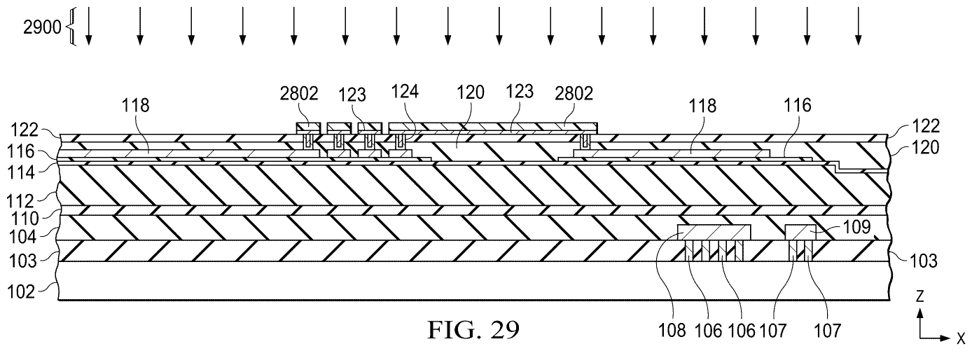

Another implementation can include patterning and etching the bilayer of 123 and 2802 in one continuous etch process, where the patterning includes depositing the protective layer 2802 and a bottom anti-reflective coating (BARC) layer 2804 and forming a patterned resist 2806 as shown in FIG. 28. A process 2800 in FIG. 28 in this example patterns the TFR prior to etching. FIG. 29 depicts the result of the pattern/etch process 2900 after post etch cleanup, where the etching process (not shown) etches the BARC layer 2804, the protective layer 2802 and the TFR layer 123 in one chamber/process recipe. Then FIG. 29 properly follows as the 2900 being the etch process and cleanup to achieve the diagram as it is currently shown.)

At 256 in FIG. 2, the TFR layer 123 is etched to form the desired patterned thin-film resistor features (e.g., resistors R1 and R2 described above in connection with FIGS. 1 and 1A). FIG. 29 shows one example, in which an etch process 2900 is performed using the patterned protective layer 2802 (including photoresist and BARC layer, if used) to selectively etch the TFR layer 123. An O₂ ash process followed by a dilute HF clean can be used to remove the resist 2806 and underlying BARC. In another implementation, the processing 2900 can include a post-ash solvent cleaning step.

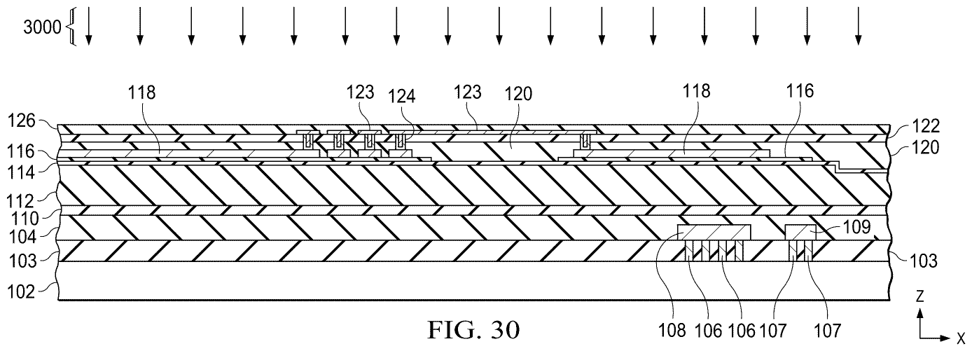

At 258 in FIG. 2, a top sub layer (e.g., the dielectric sublayer 126 in FIG. 1 above) of the dielectric seal structure 121 is formed to enclose the TFR layer 123 in a hermetic seal structure. FIG. 30 shows one example, in which the dielectric sublayer 126 implemented as an upper SiON dielectric seal layer (e.g., a fourth SiON layer) is formed by a deposition process 3000 of any suitable stoichiometry and thickness (e.g., approximately 0.1 μm) over the patterned features of the TFR layer 123 and the top surface of the dielectric layer 122.

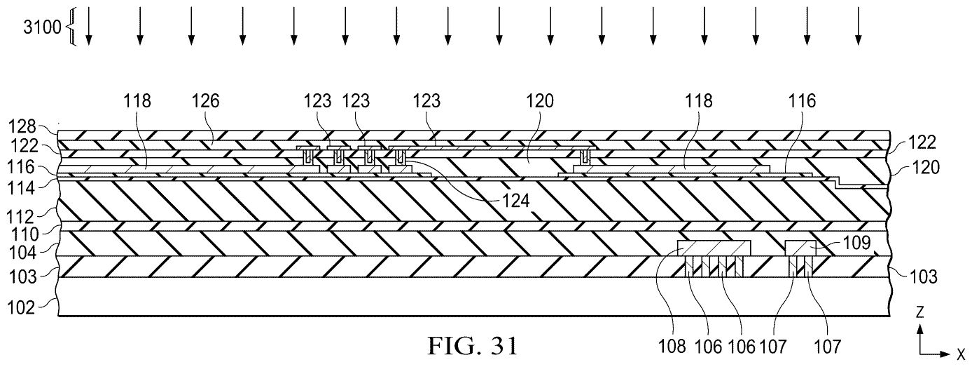

At 260-264 in FIG. 2, the method 200 in one example includes forming a protective overcoat (PO) bilayer including further silicon dioxide or other dielectric layer over the seal structure 121 and a dielectric layer over the silicon dioxide. At 260, the dielectric layer 128 is deposited over the dielectric seal structure 121. FIG. 31 shows one example, in which a PECVD deposition process 3100 is performed that deposits a silicon dioxide layer, e.g., TEOS oxide, as dielectric layer 128, having any suitable stoichiometry and thickness (e.g., approximately 1.0 μm) over (e.g., on and directly contacting) the top surface of the dielectric sublayer 126.

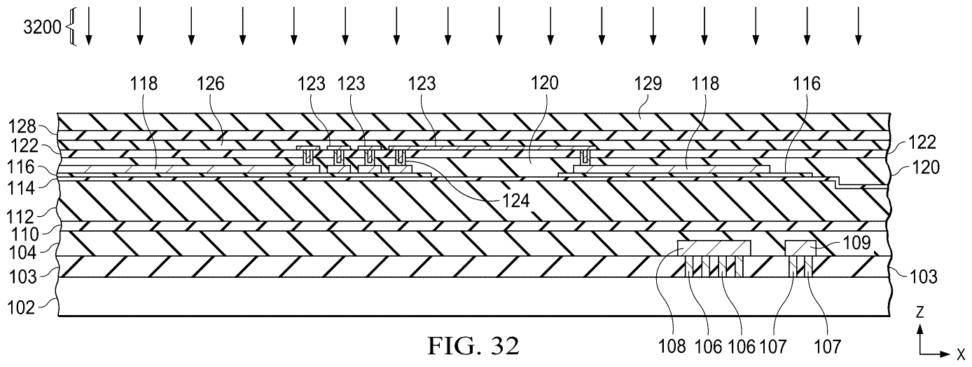

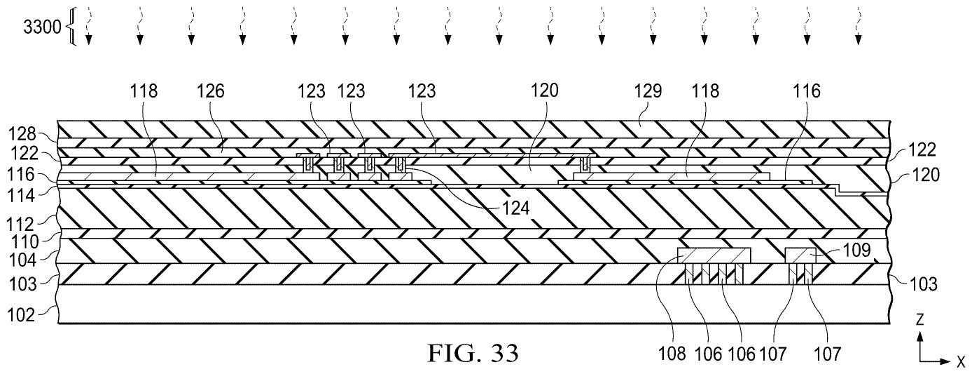

At 262 in FIG. 2, an upper protective overcoat layer is formed. FIG. 32 shows one example, in which a deposition process 3200 is performed that deposits the dielectric layer 129, e.g., a fifth silicon oxynitride layer, of any suitable stoichiometry and thickness (e.g., approximately 2.8 μm) over (e.g., on and directly contacting) the top surface of the dielectric layer 128. At 264 in FIG. 2, the method 200 in one example further includes annealing. FIG. 33 shows one example, in which a thermal process 3300 is performed that anneals the structure, for example using N₂ at approximately 400-450 degrees C., to drive underlying metals into more tensile state to help limit the wafer bow due to all the compressive dielectric depositions.

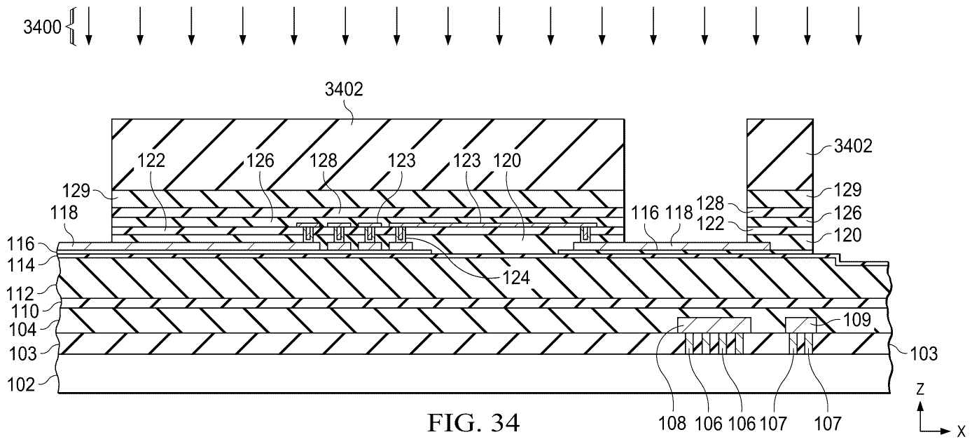

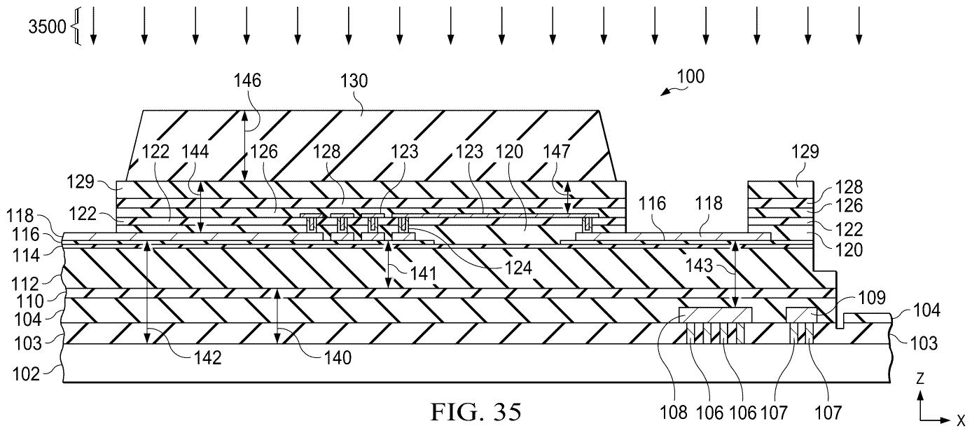

The method 200 continues at 266 and 268 in FIG. 2 with etch processing. At 266, a protective overcoat patterned etch is performed. FIG. 34 shows one example, in which an etch process 3400 is performed using an etch mask 3402 to remove exposed portions of the layers 120, 122, 126, 128, and 129 to expose portions of the top surfaces of the resistor terminals of the pad metal layer 118 to facilitate subsequent electrical connection by bond wires. The etch process 3400 in one example etches away some of the scribe region on the right side of FIG. 34 to facilitate subsequent plateau etching of that region (e.g., at 268 in FIG. 2). At 268 in FIG. 2, a plateau etch is performed using an etch mask (not shown) to etch through laterally peripheral portions of each prospective die area of a processed wafer. FIG. 35 shows one example, in which the wafer has been processed by a plateau etching process 3500 along the right-hand side scribe line region at the peripheral edge of the illustrated prospective die portion of the wafer. In one example, the method 200 also includes nitridation of exposed oxide sidewalls at 269 in FIG. 2, for example, using the process defined in US patent application publication no. US 2024/0113095 A1 published Apr. 4, 2024 (application Ser. No. 18/067,703), the entirety of which is hereby incorporated by reference. Also at 269 in FIG. 2, the polyimide layer 130 is formed over (e.g., on and directly contacting) the dielectric layer 129 above the TFR layer 123 as further shown in FIG. 35, for example using a dispense or screening process (e.g., to a thickness 146 of approximately 8-10 μm) over portions of the protective overcoat stack to create a stress barrier to mitigate mechanical stress at the surface of the dielectric layer 129 of the protective overcoat stack and also to reduce the electric fields in the eventual epoxy mold compound (EMC) over the die. As shown in FIG. 35, the polyimide layer 190 has gaps that exposes the top sides of the resistor terminals of the pad metal layer 118.

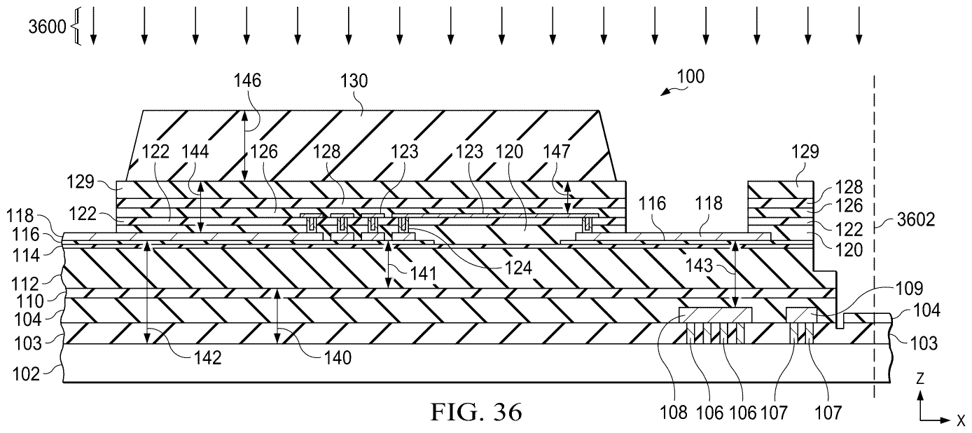

At 270 and FIG. 2, the method 200 continues with die separation to separate individual semiconductor dies from the processed wafer. FIG. 36 shows one example, in which a die separation or singulation process 3600 is performed that separates the illustrated die along a cut line 3602 in the scribe line region at the periphery of each prospective die area of the processed wafer. The method 200 continues at 272 in FIG. 2 with die attach processing (e.g., to attach the die to the die attach pad or other starting lead frame such as to the die attach pad 153 as shown in FIG. 1), as well as electrical connection (e.g., by forming the bond wires 161, 162, and 163 in FIG. 1), molding processing (e.g., to form the molded package structure 151 in FIG. 1), and any required package separation processing (e.g., to separate fabricated packaged electronic devices from a processed lead frame panel array of rows and columns of integrated circuits 100).

Described examples advantageously provide a solution to mitigate or avoid the use of discrete resistors for high voltage sensing applications or other voltage isolation applications, with the voltage divider resistors R1 and R2 of the illustrated example being provided on-chip by integration into the integrated circuit 100 on a dedicated voltage divider die of a multichip module implementation, or by incorporation into a single die of an integrated circuit device. Described examples provide silicon dioxide or other dielectric layers as a high voltage insulator between the TFR layer 123 and the underlying substrate or semiconductor layer 102, covering the TFR layer 123 with high electrical breakdown strength dielectrics and encapsulating the die within an MCM with mold compound of the package structure 151 (FIG. 1) that mitigates or prevents air breakdown over the TFR layer 123. In addition, the thin-film resistors R1 and R2 are formed above the resistor terminal metal features of the second metallization structure level (e.g., terminals 131-133 of the pad metal layer 118) to provide sufficient dielectric spacing between the TFR layer 123 and the underlying semiconductor layer 102 to facilitate high-voltage operation without voltage breakdown. Moreover, the illustrated examples provide a hermetic dielectric seal structure 121 (e.g., FIG. 1) to mitigate corrosion or other degradation of the thin-film resistors R1 and R2 to provide enhanced sensing circuit performance for high voltage isolation in a compact integrated form together with high precision thin film sensing resistors. Described examples provide a compact solution that avoids mounting discrete resistors on a host system circuit board to form a voltage divider on a PCB and instead fully integrates the resistor network onto a significantly smaller area of silicon that enables the voltage divider and the sensing circuits to co-exist within a single small outline integrated circuit (e.g., SOIC) using direct eye integration or combination with multiple semiconductor dies in a multichip module (MCM) package with significantly reduced system board area and integrated circuit device cost.

Modifications are possible in the described examples, and other implementations are possible, within the scope of the claims.

What is claimed is:

1. An integrated circuit, comprising:
a multilevel metallization structure having a dielectric layer over a semiconductor layer, a pad metal layer on the dielectric layer, and a thin-film resistor layer located over the pad metal layer, wherein the thin-film resistor layer is spaced apart from the semiconductor layer by approximately 9.0 μm or more; and
a thin-film resistor having a spiral winding of the thin-film resistor layer with multiple turns in the thin-film resistor layer, the spiral winding connected between first and second resistor terminals of the pad metal layer.

2. The integrated circuit of claim 1, wherein the thin-film resistor is a first thin-film resistor and the spiral winding is a first spiral winding, further comprising a second thin-film resistor having a second spiral winding with multiple turns of the thin-film resistor layer, the second spiral winding connected between third and fourth resistor terminals of the pad metal layer, and the turns of the second spiral winding interleaved with the turns of the first spiral winding.

3. The integrated circuit of claim 2, further comprising an outer dummy resistive layer line of the thin-film resistor layer, the outer dummy resistive layer line at least partially surrounding an outer extent of the first and second thin-film resistors.

4. The integrated circuit of claim 3, further comprising an inner dummy resistive layer line (177, 187) of the thin-film resistor layer, the inner dummy resistive layer line at least partially surrounded by an inner extent of the first and second thin-film resistors.

5. The integrated circuit of claim 1, wherein the spiral winding of the thin-film resistor layer overlies a gap in the pad metal layer.

6. The integrated circuit of claim 1, wherein the first resistor terminal is outside an outer extent of the spiral winding, and the second resistor terminal is inside an inner extent of the spiral winding.

7. The integrated circuit of claim 1, further comprising a dummy resistive layer line of the thin-film resistor layer, the dummy resistive layer line adjacent to and spaced apart from a first or last turn of the spiral winding.

8. The integrated circuit of claim 7, wherein the dummy resistive layer line is connected to one of the first and second resistor terminals.

9. The integrated circuit of claim 1, further comprising:
a conductive first vertical interconnect connected between a first end of the spiral winding of the thin-film resistor layer and the first resistor terminal of the pad metal layer; and
a conductive second vertical interconnect connected between a second end of the spiral winding of the thin-film resistor layer and the second resistor terminal of the pad metal layer.

10. The integrated circuit of claim 1, wherein the spiral winding includes linear portions of the thin-film resistor layer and turn portions of the thin-film resistor layer.

11. The integrated circuit of claim 10, wherein the turn portions are less than 180 degrees.

12. The integrated circuit of claim 11, wherein the turn portions are greater than 0 degrees and less than or equal to 90 degrees.

13. The integrated circuit of claim 1, wherein the spiral winding includes only curved portions of the thin-film resistor layer.

14. The integrated circuit of claim 1, wherein the thin-film resistor is a first thin-film resistor and the spiral winding is a first spiral winding, further comprising a second thin-film resistor having a second spiral winding having multiple turns of the thin-film resistor layer, the second spiral winding spaced apart from the first spiral winding and connected between third and fourth resistor terminals of the pad metal layer.

15. The integrated circuit of claim 14, further comprising:
a third thin-film resistor having a third spiral winding having multiple turns of the thin-film resistor layer, the third spiral winding spaced apart from the first spiral winding and connected between fifth and sixth resistor terminals of the pad metal layer, and the turns of the third spiral winding interleaved with the turns of the first spiral winding; and
a fourth thin-film resistor having a fourth spiral winding having multiple turns of the thin-film resistor layer, the fourth spiral winding spaced apart from the second spiral winding and connected between seventh and eighth resistor terminals of the pad metal layer, and the turns of the fourth spiral winding interleaved with the turns of the second spiral winding.

16. An integrated circuit, comprising:
a multilevel metallization structure having a dielectric layer over a semiconductor layer, a pad metal layer on the dielectric layer, and a thin-film resistor layer located over the pad metal layer;
a first thin-film resistor having a first spiral winding with multiple turns in the thin-film resistor layer, the first spiral winding connected between first and second resistor terminals of the pad metal layer; and
a second thin-film resistor spaced apart from the first thin-film resistor and having a second spiral winding with multiple turns in the thin-film resistor layer, the second spiral winding connected between the second resistor terminal and a third resistor terminal of the pad metal layer.

17. The integrated circuit of claim 16, wherein:
the first resistor terminal is inside an inner extent of the first spiral winding;
the second resistor terminal is outside the outer extents of the first and second spiral windings; and
the third resistor terminal is inside an inner extent of the second spiral winding.

18. The integrated circuit of claim 16, further comprising:
a third thin-film resistor having a third spiral winding with multiple turns in the thin-film resistor layer, the third spiral winding connected between fourth and fifth resistor terminals of the pad metal layer, and the turns of the third spiral winding interleaved with the turns of the first spiral winding; and
a fourth thin-film resistor having a fourth spiral winding with multiple turns of the thin-film resistor layer, the fourth spiral winding connected between the fifth resistor terminal and a sixth resistor terminal of the pad metal layer, and the turns of the fourth spiral winding interleaved with the turns of the second spiral winding.

19. The integrated circuit of claim 18, wherein:
the fourth resistor terminal is inside an inner extent of the third spiral winding;
the fifth resistor terminal is outside the outer extents of the third and fourth spiral windings; and
the sixth resistor terminal is inside an inner extent of the fourth spiral winding.

20. The integrated circuit of claim 16, wherein the first and second spiral windings of the thin-film resistor layer overlie respective gaps in the pad metal layer.

21. The integrated circuit of claim 16, further comprising a dummy resistive layer line of the thin-film resistor layer, the dummy resistive layer line adjacent to and spaced apart from a first or last turn of one of the first and second spiral windings.

22. The integrated circuit of claim 21, wherein the dummy resistive layer line is connected to one of the resistor terminals.

23. The integrated circuit of claim 16, wherein the first spiral winding includes linear portions of the thin-film resistor layer and turn portions of the thin-film resistor layer.

24. The integrated circuit of claim 23, wherein the turn portions are less than 180 degrees.

25. The integrated circuit of claim 16, wherein the first spiral winding includes only curved portions of the thin-film resistor layer.
